(19) United States
(12) Patent Application Publication
(10) Pub. No.: US 2026/0112445 A1
(43) Pub. Date: Apr. 23, 2026

(54) MANAGING FAILURES OF IN-MEMORY COMPUTER (IMC) DEVICES

(71) Applicant: Macronix International Co., Ltd., Hsinchu (TW)

(72) Inventors: Chin-Hung Chang, Tainan (TW); Yen-Ning Chiang, Zhubei (TW); Lochuan Liang, New Taipei (TW)

(73) Assignee: Macronix International Co., Ltd., Hsinchu (TW)

(21) Appl. No.: 19/260,970

(22) Filed: Jul. 7, 2025

Related U.S. Application Data
(63) Continuation-in-part of application No. 19/221,183, filed on May 28, 2025.
(60) Provisional application No. 63/710,078, filed on Oct. 22, 2024.

(51) Int. Cl. G11C 29/00; G11C 29/02

(52) U.S. Cl. CPC G11C 29/702; G11C 29/022; G11C 29/76

(57) ABSTRACT

Systems, devices, methods, and circuits for managing failures of in-memory computing (IMC) devices. An example memory device includes: a plurality of memory units and a circuitry configured for execution of a computing instruction in one or more memory units. A memory unit includes: a memory cell array and a peripheral circuit including a plurality of subcircuits coupled to the memory cell array. Each subcircuit includes: one or more internal sense amplifiers, one or more latches, and one or more multipliers. The circuitry is configured to: determine whether a subcircuit is defective by determining whether at least one of an internal sense amplifier, a latch, or a multiplier in the subcircuit is defective using an external sense amplifier external to the memory unit, and in response to determining that the subcircuit is defective, perform one or more corresponding actions including replacing the subcircuit with a redundant subcircuit in the peripheral circuit.

### CROSS-REFERENCE TO RELATED APPLICATIONS

This application is a continuation-in-part application of and claims the benefit of priority to U.S. patent application Ser. No. 19/221,183, filed May 28, 2025, which claims the benefit of U.S. Provisional Patent Application No. 63/710,078, filed Oct. 22, 2024. Those applications are hereby incorporated by reference herein in their entireties.

### TECHNICAL FIELD

The present disclosure is directed to memory devices, e.g., in-memory computing (IMC) devices or computing in memory (CIM) devices.

### BACKGROUND

With the rapid growth of data volume and the rise of technologies such as cloud computing and big data, traditional computing models are facing performance bottlenecks, and In-Memory Computing (IMC) emerged as the times require. IMC is a computing architecture that can combine data storage and computing processes in memory to reduce communication delays between a processor and a memory.

### SUMMARY

The present disclosure describes methods, devices, systems, and techniques for managing failures of in-memory computing (IMC) devices or computing in memory (CIM) devices, e.g., digital computing in memory (dCIM) devices, that can be configured to execute one or more operations in memory (e.g., Multiply-Accumulate (MAC) operation) and to perform failure analysis and repair the failures in the IMC or CIM devices.

One aspect of the present disclosure features a memory device, including: a plurality of memory units and a circuitry coupled to the plurality of memory units. A memory unit of the plurality of memory units includes: a memory cell array including memory cells and a peripheral circuit including a plurality of subcircuits. A subcircuit of the plurality of subcircuits is configured to read data from a corresponding memory cell via a corresponding bit line and output a detection result via the corresponding bit line to a sense amplifier in the circuitry, the sense amplifier being external to the memory unit. The circuitry is configured to: determine whether at least one of the corresponding memory cell or the subcircuit is defective based on a result of the sense amplifier sensing the detection result from the subcircuit, and in response to determining that the at least one of the corresponding memory cell or the subcircuit is defective, perform one or more corresponding actions.

In some implementations, the sense amplifier is a first sense amplifier, and the subcircuit includes: one or more second sense amplifiers, one or more latches, and one or more multipliers. A multiplier of the one or more multipliers includes: a first input coupled to an output of a corresponding second sense amplifier of the one or more second sense amplifiers and configured to receive the data read from the corresponding memory cell by the corresponding second sense amplifier, a second input coupled to a corresponding latch of the one or more latches and configured to receive input data from the corresponding latch, and an output configured to output a multiplication result based on the data read from the corresponding memory cell by the corresponding second sense amplifier and the input data from the corresponding latch.

In some implementations, a second sense amplifier has a smaller size and lower power consumption than the first sense amplifier, and the first sense amplifier has an operation speed than the second sense amplifier.

In some implementations, the subcircuit further includes a transistor having a first terminal coupled to the output of the corresponding second sense amplifier, a second terminal coupled to the corresponding bit line, and a gate terminal. The subcircuit is configured to: receive a gate control signal at the gate terminal of the transistor to turn on the transistor while the corresponding second sense amplifier reads the data from the corresponding memory cell via the corresponding bit line, and output the data read from the corresponding memory cell by the corresponding second sense amplifier via the corresponding bit line to the first sense amplifier.

In some implementations, the detection result includes the data read from the corresponding memory cell by the corresponding second sense amplifier, and the circuitry is configured to: determine whether at least one of the corresponding memory cell or the corresponding second sense amplifier of the subcircuit is defective based on the data read from the corresponding memory cell by the corresponding second sense amplifier.

In some implementations, the subcircuit further includes a transistor having a first terminal coupled to the output of the multiplier, a second terminal coupled to the corresponding bit line, and a gate terminal. The subcircuit is configured to: turn off a connection between the first input of the multiplier and the output of the corresponding second sense amplifier, and output, by the multiplier, an output based on the input data from the corresponding latch.

In some implementations, the detection result includes the output based on the input data from the corresponding latch, and the circuitry is configured to determine whether at least one of the corresponding input latch or the multiplier is defective based on the output that is based on the input data from the corresponding latch.

In some implementations, the subcircuit further includes a connection transistor having a first terminal coupled to the output of the corresponding second sense amplifier, a second terminal coupled to the first input of the multiplier, and a gate terminal. The connection transistor is configured to be turned off to turn off the connection between the first input of the multiplier and the output of the corresponding second sense amplifier.

In some implementations, the subcircuit further includes: a first transistor having a first terminal coupled to the output of the corresponding second sense amplifier, a second terminal coupled to the corresponding bit line, and a first gate terminal; a second transistor having a first terminal coupled to the output of the multiplier, a second terminal coupled to the second terminal of the first transistor, and a second gate terminal; and a connection transistor having a first terminal coupled to the output of the corresponding second sense amplifier, a second terminal coupled to the first input of the multiplier, and a connection gate terminal.

In some implementations, the subcircuit is configured to: turn off the connection transistor and the second transistor, and turn on the first transistor to output the data read from the corresponding memory cell by the corresponding second sense amplifier via the corresponding bit line to the first sense amplifier for determining whether at least one of the corresponding memory cell or the corresponding sense amplifier is defective, and turn off the connection transistor, and turn on the second transistor and the first transistor to output an output based on the input data from the corresponding latch via the corresponding bit line to the first sense amplifier for determining whether at least one of the corresponding input latch or the multiplier is defective.

In some implementations, the subcircuit is configured to: turn on the connection transistor, and turn off the first transistor and the second transistor, such that the multiplier receives the data read from the corresponding memory cell by the corresponding sense amplifier and the input data from the corresponding latch and generate a multiplication result based on the data read from the corresponding memory cell and the input data.

In some implementations, the one or more corresponding actions include one or more of: marking the subcircuit as a defective subcircuit, storing a corresponding address for the at least one of the corresponding memory cell or the subcircuit as a failed address in the circuitry, remapping stored data in corresponding memory cells coupled to the subcircuit to redundant memory cells coupled to a redundant subcircuit in the peripheral circuit, remapping input data loaded in the one or more latches of the subcircuit to one or more redundant latches of the redundant subcircuit, and clearing the one or more latches of the subcircuit with a value of “0”.

In some implementations, the circuitry includes a failure analysis controller including: a comparator coupled to the sense amplifier and configured to compare the result of the sense amplifier sensing the detection result transmitted from the subcircuit and corresponding reference data stored in the failure analysis controller and a register configured to store a corresponding address for defective data in the memory cell array or a defective subcircuit as a failed address.

In some implementations, the peripheral circuit includes: a sense amplifier circuit coupled to the memory cell array, the sense amplifier circuit including a plurality of sense amplifiers in the plurality of subcircuits, an input latch circuit including a plurality of input latches in the plurality of subcircuits, a multiplier circuit coupled to the sense amplifier circuit and the input latch circuit, the multiplier circuit including a plurality of multipliers in the plurality of subcircuits, and an adder circuit coupled to the multiplier circuit.

In some implementations, the circuitry is configured for execution of a computing instruction in one or more memory units of the plurality of memory units, the one or more memory units including the memory unit, and where the peripheral circuit of the memory unit is configured to perform a computing operation corresponding to the computing instruction. The sense amplifier circuit is configured to read weight data from corresponding memory cells in the memory cell array, where the input latch circuit is configured to receive input data from the circuitry, where the multiplier circuit is configured to multiply the weight data by the input data to obtain a plurality of multiplication results, and where the adder circuit configured to add the plurality of multiplication results to obtain a sum corresponding to the computing operation.

In some implementations, the input data includes a data vector having a plurality of vector values, the weight data includes a plurality of weights, and a number of the plurality of weights is identical to a number of the plurality of vector values, and the multiplier circuit is configured to multiply each of the plurality of weights by a corresponding vector value of the plurality of vector values to obtain a corresponding multiplication result of the plurality of multiplication results.

In some implementations, the circuitry includes a global adder configured to generate a computing result for the computing instruction based on one or more sums obtained from one or more adder circuits of the one or more memory units.

In some implementations, the memory device is a NOR flash memory device, and the computing operation includes a Multiply-Accumulate (MAC) operation.

Another aspect of the present disclosure features a memory device including: a plurality of memory units and a circuitry coupled to the plurality of memory units and configured for execution of a computing instruction in one or more memory units of the plurality of memory units, the circuitry including a first sense amplifier external to the plurality of memory units. A memory unit of the plurality of memory units includes: a memory cell array including memory cells and a peripheral circuit including a plurality of subcircuits coupled to the memory cell array, each subcircuit of the plurality of subcircuits including: one or more second sense amplifiers, one or more latches, and one or more multipliers. The circuitry is configured to: determine whether a subcircuit is defective by determining whether at least one of a second sense amplifier, a latch, or a multiplier in the subcircuit is defective using the first sense amplifier, and in response to determining that the subcircuit is defective, perform one or more corresponding actions including replacing the subcircuit with a redundant subcircuit in the peripheral circuit.

In some implementations, the circuitry is configured to: remap stored data in corresponding memory cells coupled to the subcircuit to redundant memory cells coupled to a redundant subcircuit, and remap input data loaded in the one or more latches of the subcircuit to one or more redundant latches of the redundant subcircuit.

In some implementations, the peripheral circuit includes an adder circuit coupled to the plurality of subcircuits, and the circuitry is configured to, in response to determining that the subcircuit is defective, clear the one or more latches of the subcircuit with a value of “0”.

In some implementations, the subcircuit further includes: one or more first transistors, each of the one or more first transistors being coupled between a second sense amplifier of the one or more second sense amplifiers and a bit line that is coupled to the first sense amplifier. The second sense amplifier is configured to read data from a memory cell via the bit line and output the data read by the second sense amplifier through the first transistor via the bit line to the first sense amplifier. The circuitry is configured to: determine whether the second sense amplifier of the subcircuit is defective based on a result of the first sense amplifier sensing the data read from the memory cell by the second sense amplifier.

In some implementations, the subcircuit further includes: one or more second transistors, each of the one or more second transistors being coupled between a corresponding multiplier of the one or more multipliers and a corresponding bit line. The subcircuit is configured to: turn off a connection between the corresponding multiplier and a corresponding second sense amplifier, and output, by the corresponding multiplier, an output based on input data from a corresponding latch via the corresponding bit line to the first sense amplifier. The circuitry is configured to determine whether at least one of the corresponding latch or the corresponding multiplier is defective based on a result of the first sense amplifier sensing the output by the corresponding multiplier.

In some implementations, the subcircuit further includes: a connection transistor having a first terminal coupled to an output of the corresponding second sense amplifier, a second terminal coupled to a first input of the corresponding multiplier, and a connection gate terminal. The output of the corresponding sense amplifier is coupled to a first terminal of a corresponding first transistor, and the corresponding bit line is coupled to a second terminal of the corresponding first transistor, and the second transistor includes a first terminal coupled to an output of the corresponding multiplier, and a second terminal coupled to the first terminal of the corresponding first transistor.

In some implementations, the subcircuit is configured to: turn off the connection transistor and the second transistor, and turn on the corresponding first transistor to output data read from a corresponding memory cell by the corresponding second sense amplifier via the corresponding bit line to the first sense amplifier for determining whether the corresponding second sense amplifier is defective, and turn off the connection transistor, and turn on the second transistor and the corresponding first transistor to output the output based on the input data from the corresponding latch via the corresponding bit line to the first sense amplifier for determining whether at least one of the corresponding input latch or the multiplier is defective.

In some implementations, the subcircuit is configured to: turn on the connection transistor, and turn off the first transistor and the second transistor for the execution of the computing instruction, such that the multiplier receives the data read from the corresponding memory cell by the corresponding sense amplifier and the input data from the corresponding latch and generate a multiplication result based on the data read from the corresponding memory cell and the input data.

A further aspect of the present disclosure features a method, including: determining whether a subcircuit of a peripheral circuit of a memory unit of a memory device is defective by a first sense amplifier sensing an output of the subcircuit, where the memory device includes a plurality of memory units and a circuitry coupled to the plurality of memory units, the first sense amplifier is external to the plurality of memory units, the memory unit includes a memory cell array and the peripheral circuit having a plurality of subcircuits coupled to the memory cell array, and the subcircuit includes: one or more second sense amplifiers, one or more latches, and one or more multipliers; and in response to determining that the subcircuit is defective, performing one or more corresponding actions including replacing the subcircuit with a redundant subcircuit in the peripheral circuit.

In some implementations, performing the one or more corresponding actions includes one or more of: marking the subcircuit as a defective subcircuit, storing a corresponding address for the at least one of the corresponding memory cell or the subcircuit as a failed address in the circuitry, remapping stored data in corresponding memory cells coupled to the subcircuit to redundant memory cells coupled to the redundant subcircuit in the peripheral circuit, remapping input data loaded in the one or more latches of the subcircuit to one or more redundant latches of the redundant subcircuit, and clearing the one or more latches of the subcircuit with a value of “0”.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1 is a schematic diagram illustrating an example system including a memory device that can be an in-memory computing (IMC) device.

FIG. 2 is a schematic diagram illustrating an example memory device that can be an IMC device.

FIG. 3A is a schematic diagram illustrating an example memory device having a global adder for a number of memory units.

FIG. 3B is a schematic diagram illustrating another example memory device having a global adder and one or more secondary stage adders for a number of memory units.

FIG. 4A is a schematic diagram illustrating an example data input path from a host device to a memory device.

FIG. 4B is a schematic diagram illustrating another example data input path from a host device to a memory device.

FIG. 4C is a schematic diagram illustrating an example data output path from a memory device.

FIG. 4D is a schematic diagram illustrating another example data output path from a memory device.

FIG. 5A illustrates example instructions for MAC operation under an interface protocol such as SPI, QPI, or OPI.

FIGS. 5B-5D illustrates flow charts of example processes for executing the instructions under the interface protocol of FIG. 5A.

FIG. 6A illustrates example instructions for MAC operation under an interface protocol such as LPDDR.

FIGS. 6B-6D illustrates flow charts of example processes for executing the instructions under the interface protocol of FIG. 6A.

FIG. 7 shows example timing diagrams for performing an MAC operation under an interface protocol.

FIG. 8A illustrates an example MAC operation.

FIG. 8B-8E illustrate example configuration registers for the MAC operation of FIG. 8A.

FIG. 9 is a flow chart of an example process of a method for managing an in-memory computing device.

FIGS. 10A-10B are schematic diagrams illustrating an example memory unit in a memory device.

FIG. 10C illustrates an example of repairing a defective column in the memory unit of FIGS. 10A-10B.

FIG. 11A illustrates an example of performing failure analysis of a memory unit.

FIG. 11B illustrates another example of performing failure analysis of a memory unit.

FIG. 12 is a flow chart of an example process of a method for managing failures of a memory device.

Like reference numbers and designations in the various drawings indicate like elements. It is also to be understood that the various exemplary implementations shown in the figures are merely illustrative representations and are not necessarily drawn to scale.

### DETAILED DESCRIPTION

Implementations of the present disclosure provide methods, devices, systems, and techniques for managing in-memory computing (IMC) devices or computing in memory (CIM) devices, e.g., digital computing in memory (dCIM) devices, that can be configured to execute one or more operations in memory, e.g., Multiply-Accumulate (MAC) operation. Note that the terms “in-memory computing (IMC)” and “computing in memory (CIM)” can be used interchangeably in the present disclosure.

The techniques provide protocols, instructions, and configurations for IMC devices that can be configured for implementing one or more computing operations or functions. For illustration purpose, an MAC operation is described as an example computing operation in the present disclosure. However, it is noted that the techniques implemented in the present disclosure can be also used for implementing other computing operations or other functions.

Implementations of the present disclosure provide schemes for executing MAC operations in the IMC devices. The IMC devices can be implemented with a global adder and/or one or more secondary stage adders for adding multiplication results of the MAC operations to obtain MAC computing results. The techniques can provide configurable MAC operations in the IMC devices, e.g., by managing configuration registers and/or command inputs. The configuration registers can contain information of activation dimension, weight dimension, weight/activation format, MAC operation parallelism setting, interface switching, and/or read content selection. The techniques can support different types of protocols, including but not limited to, Serial Peripheral Interface (SPI), Queued Serial Peripheral Interface (QPI), Octal Peripheral Interface (OPI), and Low-Power Double Data Rate (LPDDR) protocol.

The IMC devices implemented in the present disclosure can achieve: 1) high performance, where the IMC devices can significantly increase data processing speed because memory is accessed much faster than disk storage; 2) low latency, where computing in memory reduces data transfer time between a host device and one or more memory devices; 3) real-time data processing, which enables to analyze and process large amounts of data in real time and is ideal for applications that require fast response, such as inference real-time processing to make predictions; and 4) efficiency improvement, where input/output (I/O) operations are reduced, and energy consumption and hardware requirements are reduced that enable to make the system operate more efficiently.

Implementations of the present disclosure also provide managing failures of IMC devices, e.g., by performing failure analysis in a memory unit of an IMC device and repairing a damage memory or a defective subcircuit in the memory unit. In some implementations, the IMC device includes a plurality of memory units and a circuitry coupled to the plurality of memory units. The circuitry can be configured for execution of a computing instruction in one or more memory units of the plurality of memory units. A memory unit can include a memory cell array and a peripheral circuit coupled to the memory cell array. The peripheral circuit can include a plurality of subcircuits, and each subcircuit can include one or more internal sense amplifiers, one or more input latches, and one or more multipliers. The circuitry can be configured to: determine whether a subcircuit is defective by determining whether at least one of an internal sense amplifier, a latch, or a multiplier in the subcircuit is defective using a sense amplifier external to the memory unit, and in response to determining that the subcircuit is defective, perform one or more corresponding actions including remapping data to a redundant subcircuit in the peripheral circuit. Note that the external sense amplifier is for data readout, and the internal sense amplifier is for a computation operation such as an MAC operation.

The techniques can provide a failure analysis approach to repair memory cells, internal sense amplifiers, input latches, and/or multipliers of a defective subcircuit in the memory unit. The techniques can leverage circuits (e.g., external sense amplifiers and failure analysis controllers) to accomplish failure analysis on the memory cells, the internal sense amplifiers, the input latches, and/or the multipliers. The techniques can effectively repair the defective memory cells, internal sense amplifiers and/or input latches and/or multipliers, which can improve a perplexity in predictive capability of a Machine Learning (ML) or Artificial Intelligence (AI) model such as a language model.

The techniques can be applied to various types of non-volatile memory devices, such as NOR flash memory, NAND flash memory, among others, or volatile memory devices, such as Random Access Memory (RAM) such as Dynamic random-access memory (DRAM) or Static random-access memory (SRAM). The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, computing network devices such as network routers or network processors, cache controllers and translation lookaside buffers, lookup tables, database engines, data compression hardware, artificial neural networks, intrusion prevention systems, custom computer, among others.

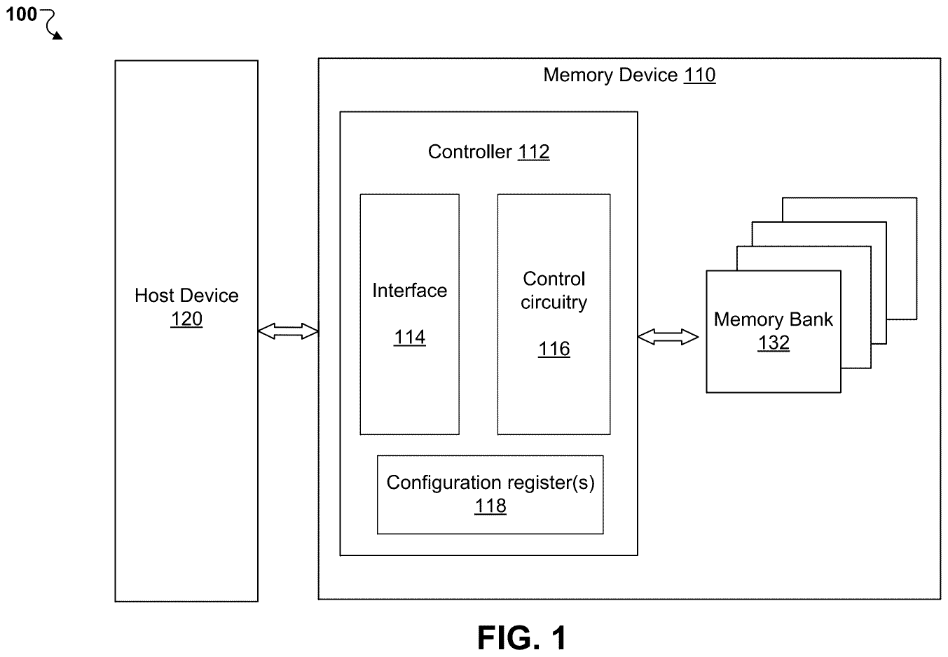

FIG. 1 is a schematic diagram illustrating an example system 100 including a memory device 110 that can be an in-memory computing (IMC) device or a CIM device. The system 100 can includes a host device 120 coupled to the memory device 110 and configured to control operations, e.g., in memory computing such as MAC operations, in the memory device 110.

The host device 120 can include a host controller that can include at least one processor and at least one memory coupled to the at least one processor and storing programming instructions for execution by the at least one processor to perform one or more corresponding operations. For example, the at least one processor can include: e.g., a central processing unit (CPU), a graphics processing unit (GPU), a multi-core Processor, a data processing unit (DPU), a tensor processing unit (TPU), a quantum processing unit (QPU), an Application Specific Integrated Circuit (ASIC), a Field Programmable Gate Array (FPGA), a microprocessor, or any other processing device, or a combination thereof.

The memory device 110 includes a controller 112 and one or more memory banks 132. The controller 112 can be implemented as a circuitry 112 that can include at least one interface 114 and a control circuitry 116. The at least one interface 114 is coupled to the host device 120 and the control circuitry 116. The control circuitry 116 is coupled between the at least one interface 114 and the one or more memory banks 132.

The at least one interface 114 is configured to receive input data (e.g., a data vector or data matrix) and/or a command/or a computing instruction from the host device 120 and output the received data/command/instruction to the control circuitry 116. The at least one interface 114 is also configured to output data, e.g., a computing result, from the control circuitry 116 to the host device 120.

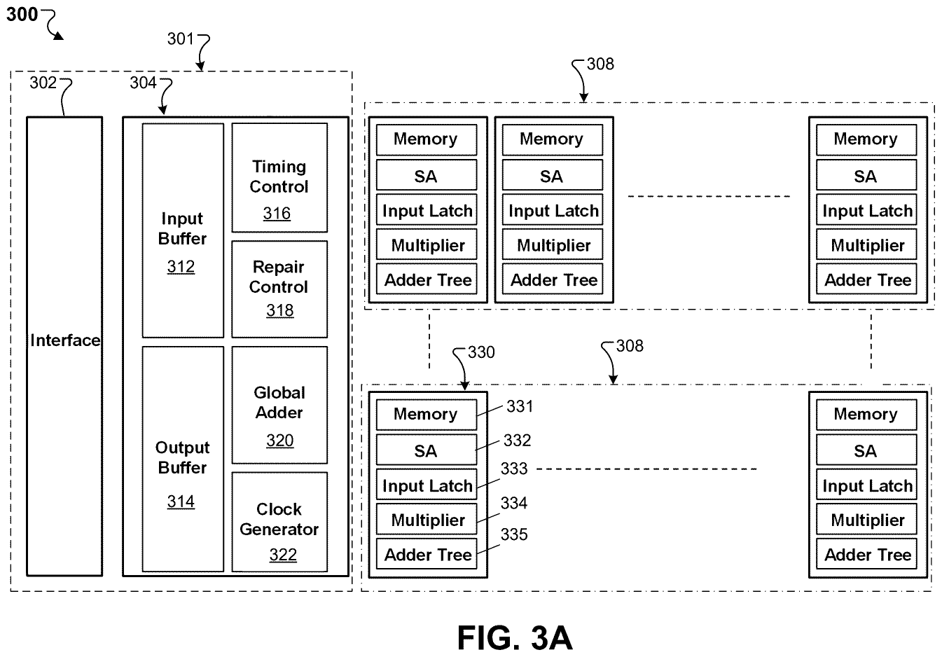

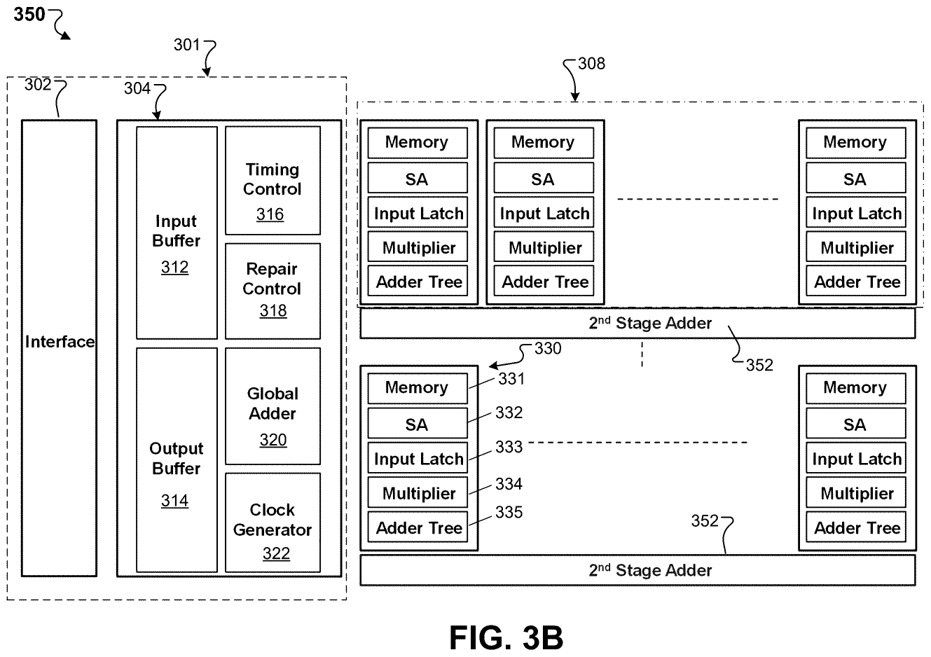

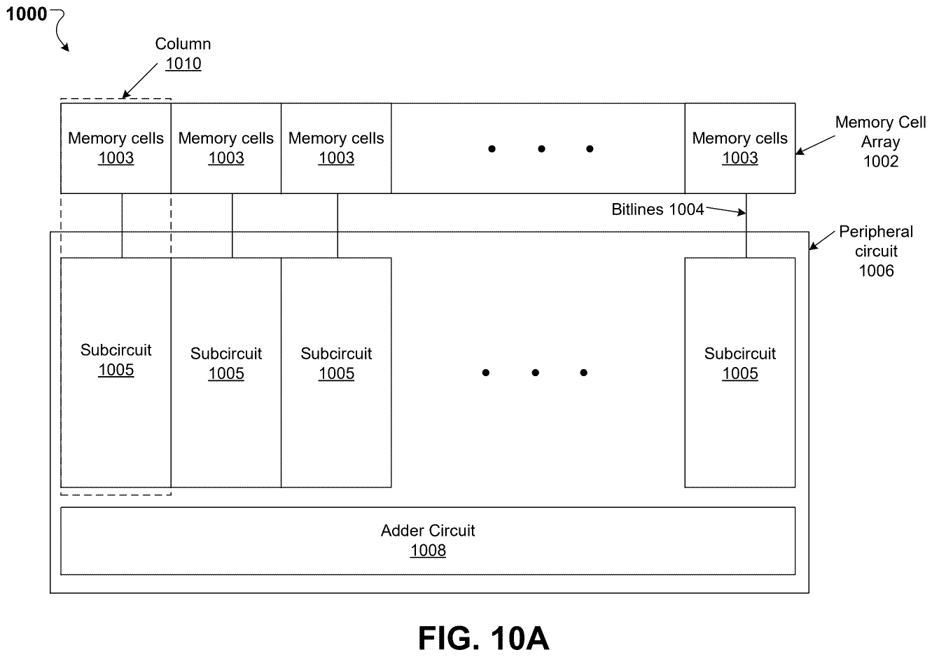

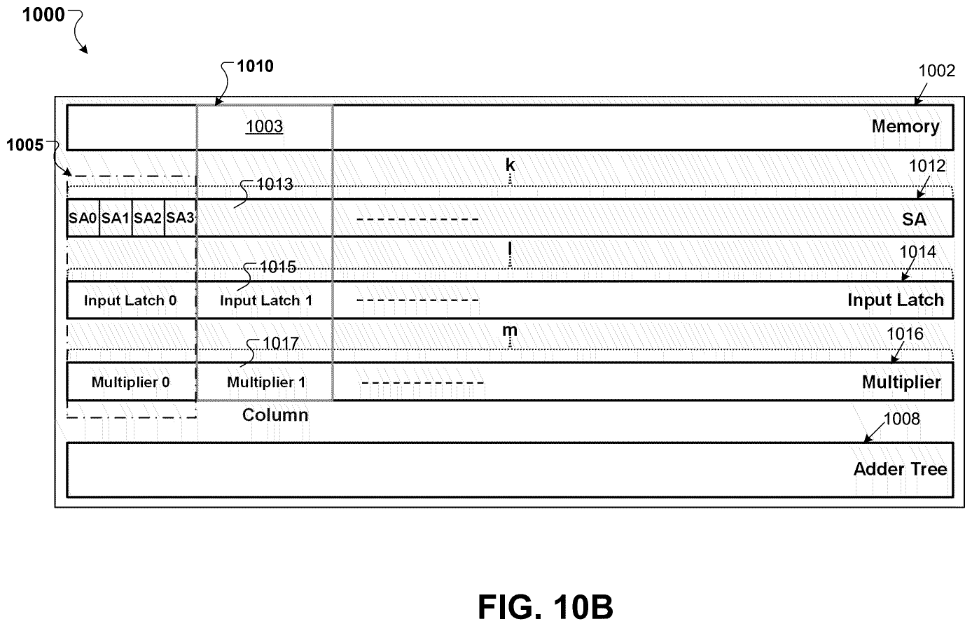

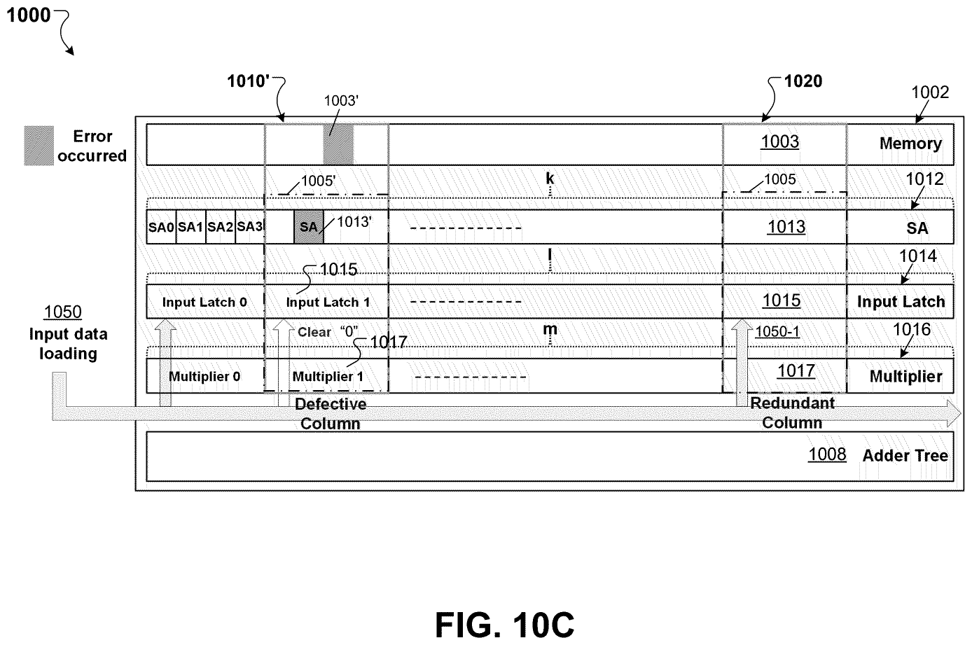

A memory bank 132 can include a two-dimensional (2D) memory device or a three-dimensional (3D) memory device. In some implementations, the memory bank 132 is a non-volatile memory that is configured for long-term storage of instructions and/or data, e.g., a NOR flash memory device, an NAND flash memory device, or some other suitable non-volatile memory device. As described with further details in FIGS. 3A-3B, each memory bank 132 can include one or more memory units (e.g., a row of memory units). A memory unit can include a memory cell array, e.g., an NOR memory cell array. Each memory unit can function as a computation tile (e.g., an MAC tile) for performing one or more computation operations (e.g., an MAC operation). As discussed with further details in FIGS. 10A-10C, a memory unit can include a memory cell array including a number of memory cells, a sense amplifier (SA) circuit including a number of SAs, an input latch circuit including a number input latches, a multiplier circuit including a number of multipliers, and an adder circuit.

A memory unit can be configured to store weight data or embedding data for one or more models (e.g., a machine learning (ML) model or an artificial intelligence (AI) model) that correspond to the particular function. Weight data or embedding data for each model can be stored in respective regions (e.g., word lines) of the memory unit or a memory bank 132. Each model can correspond to a starting address for the stored weight data or embedding data in the memory unit or the memory bank 132. The host device 120 can send a computing instruction or a command to execute the particular function for a model by including information of a corresponding starting address in one or more memory units of the one or more memory banks 132, such that the controller 112 can read stored weight data or embedding data from the one or more memory units based on the information of the corresponding starting address and execute a computing operation of the particular function for the model.

In some implementations, the system 100 includes a plurality of memory devices 110. Each memory device 110 can include one or more memory banks 132 and be configured to perform a respective function that can be different from each other. Each memory device 110 can be coupled to the host device 120. The plurality of memory device 110 can be integrated in a chiplet. In some implementations, two or more memory devices 110 can be stacked together, e.g., to provide a large storage density.

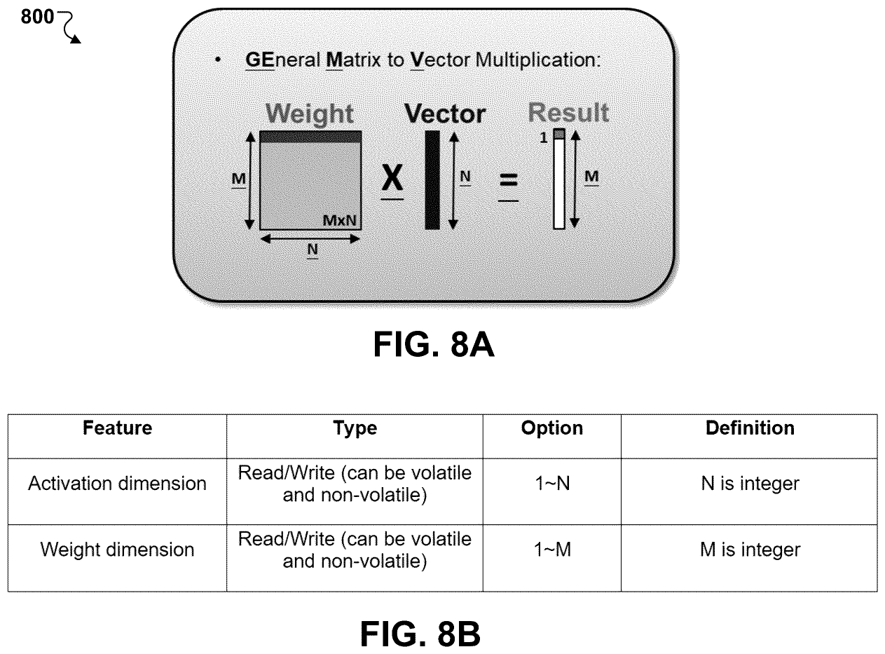

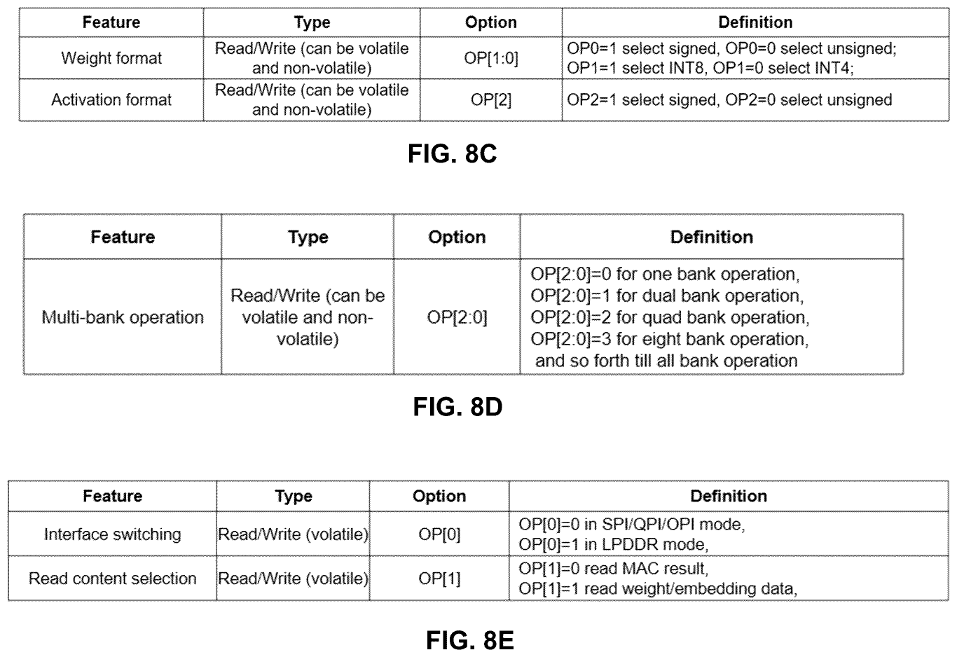

In some implementations, the controller 112 includes one or more configuration registers 118. The one or more configuration registers 118 can be included in the control circuitry 116 or external to the control circuitry 116. The computing operation in the one or more memory banks 132 can be configurable through a command input and/or configuring the one or more configuration registers 118. Each configuration register 118 corresponds to a feature and stores an option code to set up the feature, and the controller 112 is configured to set the option code for each of the one or more configuration registers 118. The one or more configuration registers 118 can be configured to be pre-set by the host device 120 before sending a command for execution of the computing operation to the memory device 110. A configuration register 118 can be implemented using one or more logic units, e.g., ADD, OR, NAND, NOR, SRAM, Flip-flop (FF) such as D-type FF, and/or latch such as Set-Reset (SR) latch. As discussed with further details in FIGS. 8B-8E, the computing operation such as MAC operation can be configurable by the one or more configuration registers.

In some examples, the one or more configuration registers 118 include at least one of: a configuration register for an activation dimension representing a length of the input data, where the option code for the activation dimension represents an integer N, e.g., as illustrated in FIG. 8B, a configuration register for an activation format, where the option code for the activation format represents sign information of the integer N, e.g., as illustrated in FIG. 8C, a configuration register for a weight dimension representing a size of the stored data, where the option code for the weight dimension represents an integer M, e.g., as illustrated in FIG. 8B, a configuration register for a weight format representing sign information of the integer M and a number of bits for representing a range of the weight dimension, e.g., as illustrated in FIG. 8C, or a configuration register for selecting a number of the one or more memory units or memory banks 132 for executing the computing instruction in parallel, where the option code specifies the number of the one or more memory units or memory banks 132, e.g., as illustrated in FIG. 8D.

In some implementations, the interface for the memory device 110 can be switchable. For example, the one or more configuration registers 118 can include at least one of: a configuration register for switching a protocol for the at least one interface 114 between a first interface protocol and a second interface protocol, e.g., as illustrated in FIG. 8E. The first interface protocol can include a Low-Power Double Data Rate (LPDDR) protocol, and the second interface protocol can include one of Serial Peripheral Interface (SPI), Queued Serial Peripheral Interface (QPI), or Octal Peripheral Interface (OPI). For example, the configuration register can be written through the second interface protocol to switch from the second interface protocol to the first interface protocol, or the configuration register can be written through the first interface protocol to switch from the first interface protocol to the second interface protocol.

In some implementations, the read content from the memory device 110 can be selectable. For example, the one or more configuration registers 118 can include a configuration register for a read command to switch a read content between the computing result and the stored data, e.g., as illustrated in FIG. 8E.

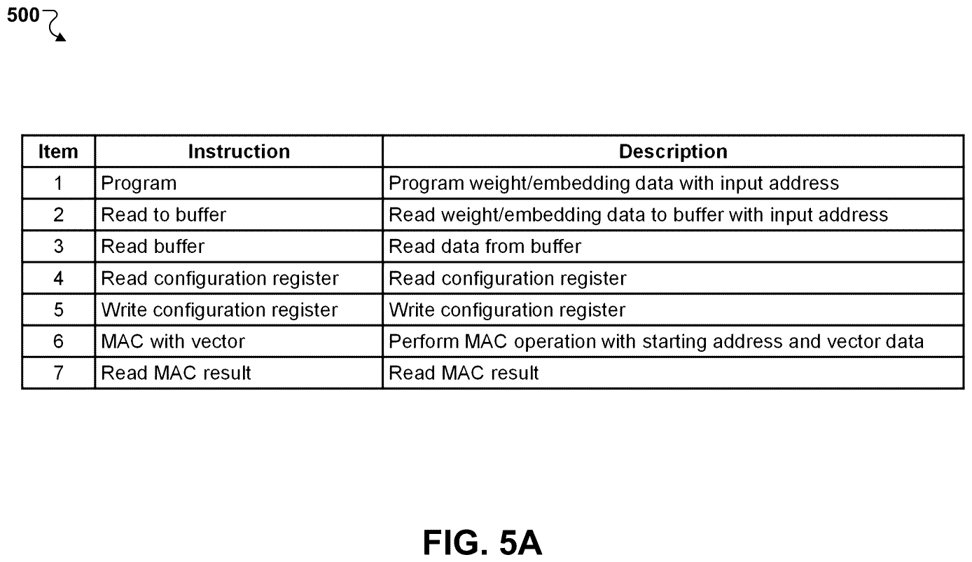

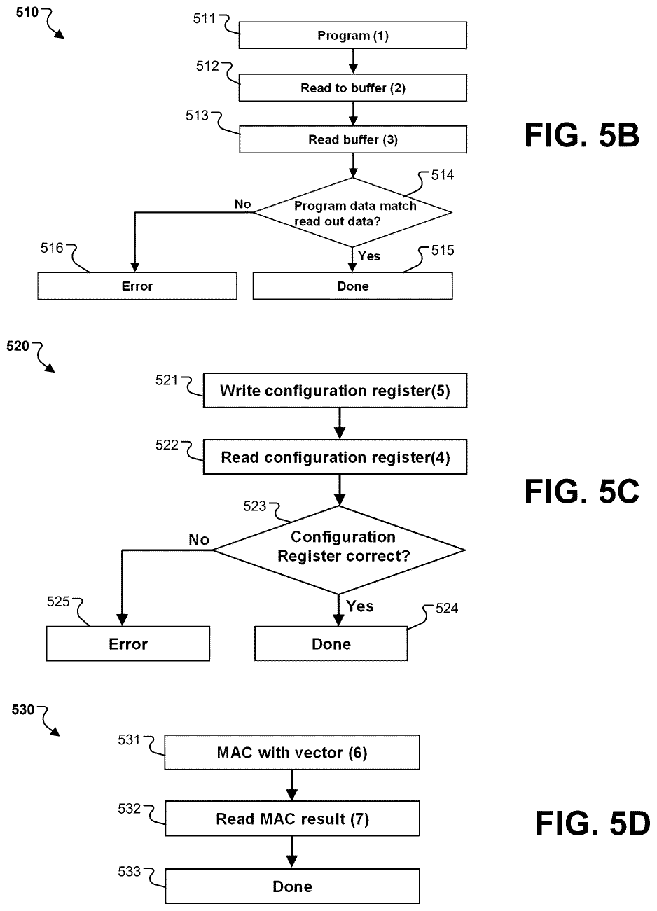

In some implementations, the at least one interface 114 includes an input/output (I/O) interface configured according to an interface protocol that can include one of Serial Peripheral Interface (SPI) protocol, Queued Serial Peripheral Interface (QPI) protocol, or Octal Peripheral Interface (OPI) protocol. As an example, corresponding instructions for MAC operation under the SPI/QPI/OPI protocol are illustrated with further details in FIGS. 5A-5D.

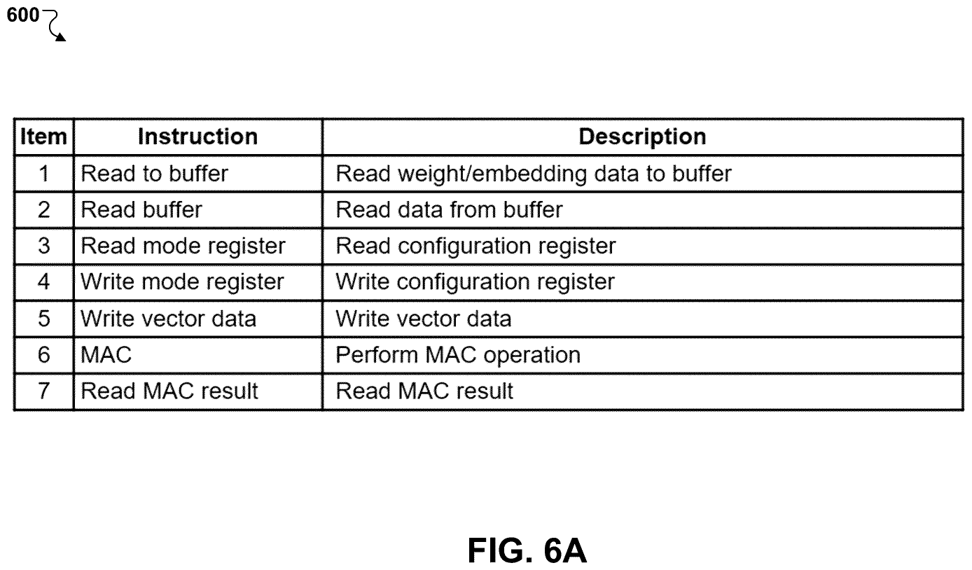

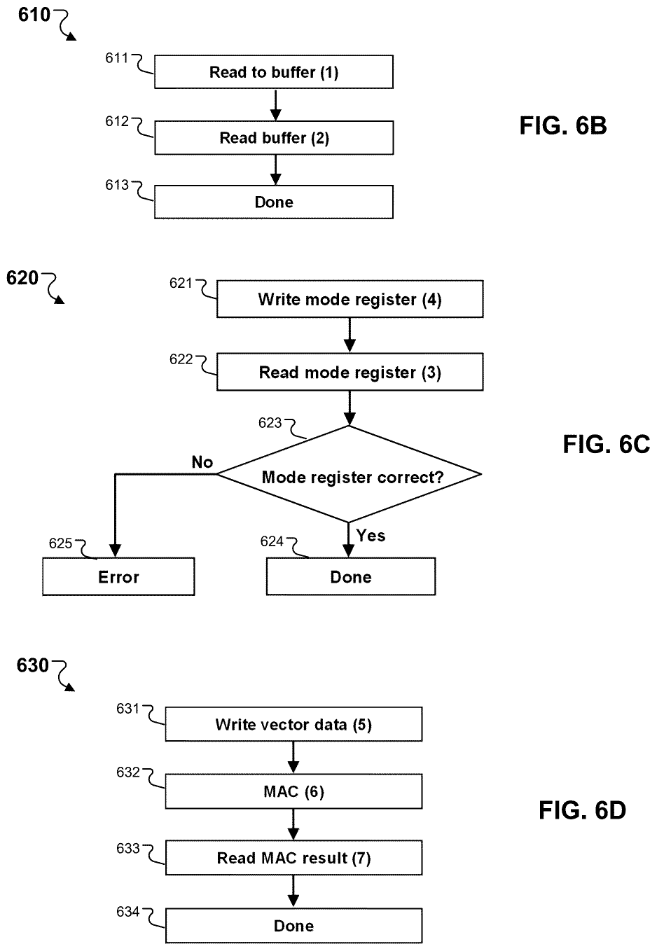

In some implementations, the at least one interface 114 includes: a first interface configured according to an LPDDR protocol and a second interface configured according to one of a SPI protocol, a QPI protocol, or an OPI protocol, e.g., as illustrated with further details in FIGS. 6A-6D. The second interface can be configured for programming respective stored data in the one or more memory banks 132. The first interface can be configured for at least one of setting up one or more corresponding configuration registers 118, transferring input data to the plurality of memory banks 132, executing the computing instruction on the input data and the respective stored data in the one or more memory banks 132, or outputting the computing result to the first interface.

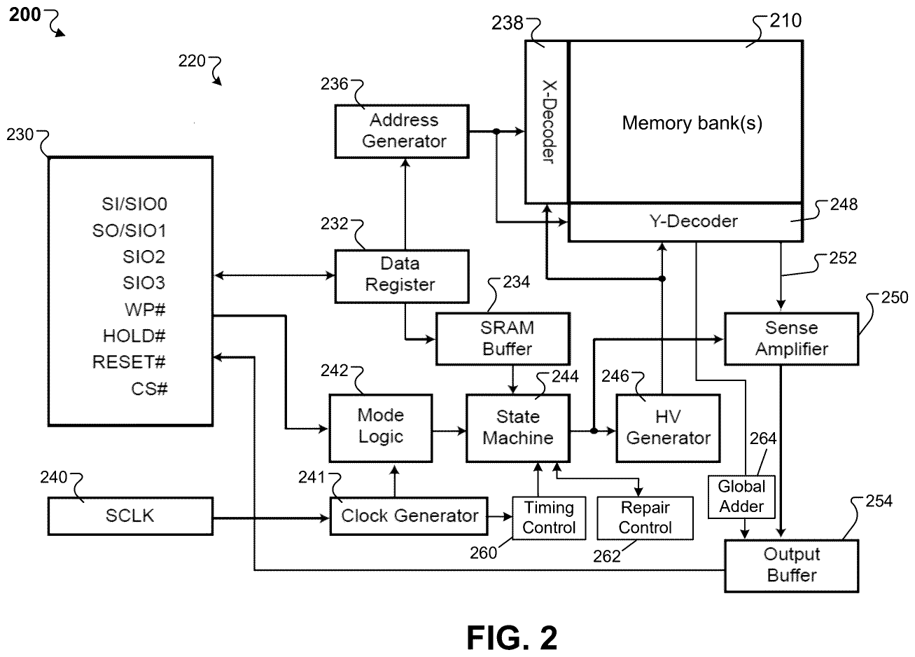

FIG. 2 is a schematic diagram illustrating an example memory device 200 that can be, e.g., the memory device 110 of FIG. 1. The memory device 200 can be implemented as an IMC or CIM device, e.g., a dCIM device, and configured to perform computing operations. The memory device 200 can include one or more NOR flash memory devices. In some implementations, two or more memory devices 200 can be stacked together, e.g., to increase a storge density.

As illustrated in FIG. 2, the memory device 200 includes a number of components that can be integrated onto a board, e.g., a Si-based carrier board, and be packaged. The memory device 200 can have one or more memory banks 210 and a controller 220 (e.g., the controller 112 of FIG. 1) that can include other components except the memory banks 210. The controller 220 can be a circuitry including a number of circuits/components, e.g., the circuits/components except the one or more memory banks 210 in FIG. 2. Each memory bank can include a number of memory units. As described with further details in FIG. 3A or 3B, a memory unit can include a memory cell array having a number of memory cells and a peripheral circuit coupled to the memory cell array. The memory cells can be coupled in series to a number of row word lines and a number of column bit lines. Each memory cell can include at least one memory transistor configured as a storage element to store data. The memory transistor can include a silicon-oxide-nitride-oxide-silicon (SONOS) transistor, a floating gate transistor, a nitride read only memory (NROM) transistor, or any suitable non-volatile memory MOS device that can store charges.

The memory device 200, e.g., the controller 220, can include an X-decoder (or row decoder) 238 and optionally a Y-decoder (or column decoder) 248. Each memory unit can be coupled to the X-decoder 238 via a respective word line and coupled to the Y-decoder 248 via a respective bit line. Accordingly, each memory unit can be selected by the X-decoder 238 and the Y-decoder 248 for read or write operations through the respective word line and the respective bit line.

The memory device 200, e.g., the controller 220, can include a memory interface (input/output—I/O) 230 having multiple pins configured to be coupled to an external device, e.g., the host device 120 of FIG. 1. The memory interface 230 can be configured to support one or more types of interface protocols (e.g., communication protocols with the controller) and interface instructions. The memory interface 230 can be a Serial Peripheral Interface (SPI) or any other suitable interface.

In some embodiments, the pins in the memory interface 230 can include SI/SIO0 for serial data input/serial data input & output, SO/SIO1 for serial data output/serial data input & output, SIO2 for serial data input or output, SIO3 for serial data input or output, RESET # for hardware reset pin active low, CS # for chip select. The memory interface 230 can also include one or more other pins, e.g., WP # for write protection active low, and/or Hold # for a holding signal input.

The memory device 200, e.g., the controller 220, can include a data register 232, an SRAM buffer 234, an address generator 236, a synchronous clock (SCLK) input 240, a clock generator 241, a mode logic 242, a state machine 244, and a high voltage (HV) generator 246. The SCLK input 240 can be configured to receive a synchronous clock input and the clock generator 241 can be configured to generate a clock signal for the memory device 200 based on the synchronous clock input. The mode logic 242 can be configured to determine whether there is a read or write operation and provide a result of the determination to the state machine 244.

The memory device 200, e.g., the controller 220, can also include a sense amplifier 250 that can be optionally connected to the Y-decoder 248 by a data line 252 and an output buffer 254 for buffering an output signal from the sense amplifier 250 to the memory interface 230. The sense amplifier 250 can be part of read circuitry that is used when data is read from the memory device 200. The sense amplifier 250 can be configured to sense low power signals from a bit line that represents a data bit (1 or 0) stored in a memory cell and to amplify small voltage swings to recognizable logic levels so the data can be interpreted properly. The sense amplifier 250 can also communicate with the state machine 244, e.g., bidirectionally. The sense amplifier 250 can be coupled to a column of memory cells associated with a bit line.

A host device, e.g., the host device 120 of FIG. 1, can generate commands, such as read commands and/or write commands that can be executed respectively to read data from and/or write data to the memory device 200. Data being written to or read from the one or more memory banks 210 can be communicated or transmitted between the memory device 200 and the controller and/or other components via a data bus (e.g., a system bus), which can be a multi-bit bus.

In some examples, during a read operation, the memory device 200 receives a read command from the host device through the memory interface 230. The state machine 244 can provide control signals to the HV generator 246 and the sense amplifier 250. The sense amplifier 250 can also send information, e.g., sensed logic levels of data, back to the state machine 244. The HV generator 246 can provide a voltage to the X-decoder 238 and the Y-decoder 248 for selecting a memory cell. The sense amplifier 250 can sense a small power (voltage or current) signal from a bit line that represents a data bit (1 or 0) stored in the selected memory cell and amplify the small power signal swing to recognizable logic levels so the data bit can be interpreted properly by logic outside the memory device 200. The output buffer 254 can receive the amplified voltage from the sense amplifier 250 and output the amplified power signal to the logic outside the memory device 200 through the memory interface 230.

In some examples, during a write operation, the memory device 200 receives a write command from the host device. The data register 232 can register input data from the memory interface 230, and the address generator 236 can generate corresponding physical addresses to store the input data in specified memory cells of the memory banks 210. The address generator 236 can be connected to the X-decoder 238 and Y-decoder 248 that are controlled to select the specified memory cells through corresponding word lines and bit lines. The SRAM buffer 234 can retain the input data from the data register 232 in its memory as long as power is being supplied. The state machine 244 can process a write signal from the SRAM buffer 234 and provide a control signal to the HV generator 246 that can generate a write voltage and provide the write voltage to the X-decoder 238 and the Y-decoder 248. The Y-decoder 248 can be configured to output the write voltage to the bit lines for storing the input data in the specified memory cells.

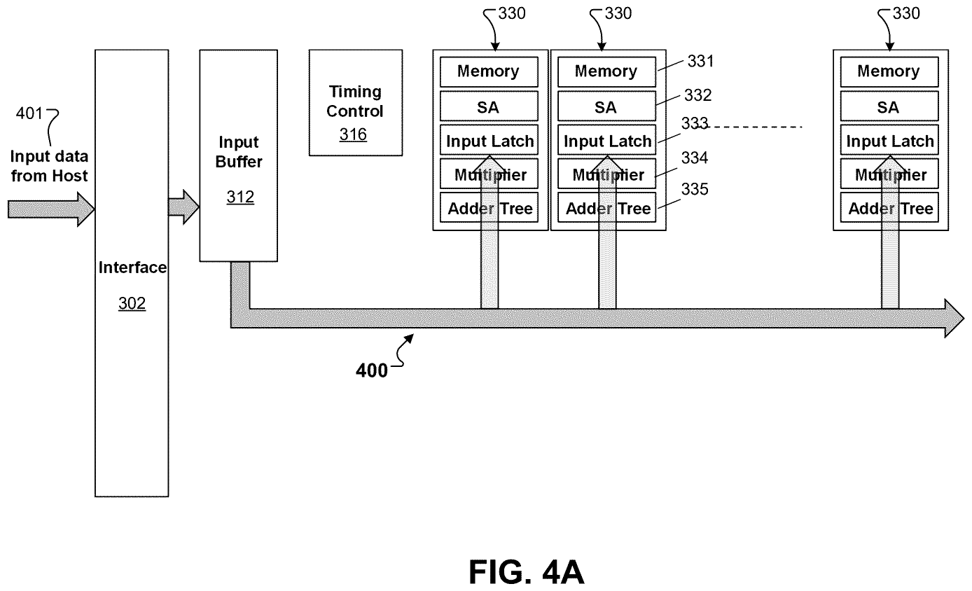

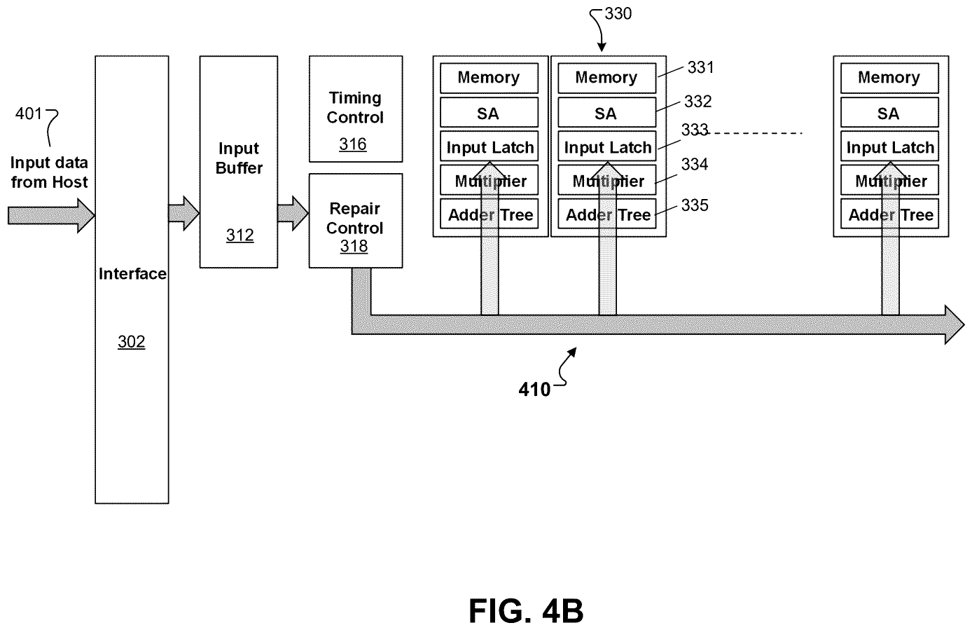

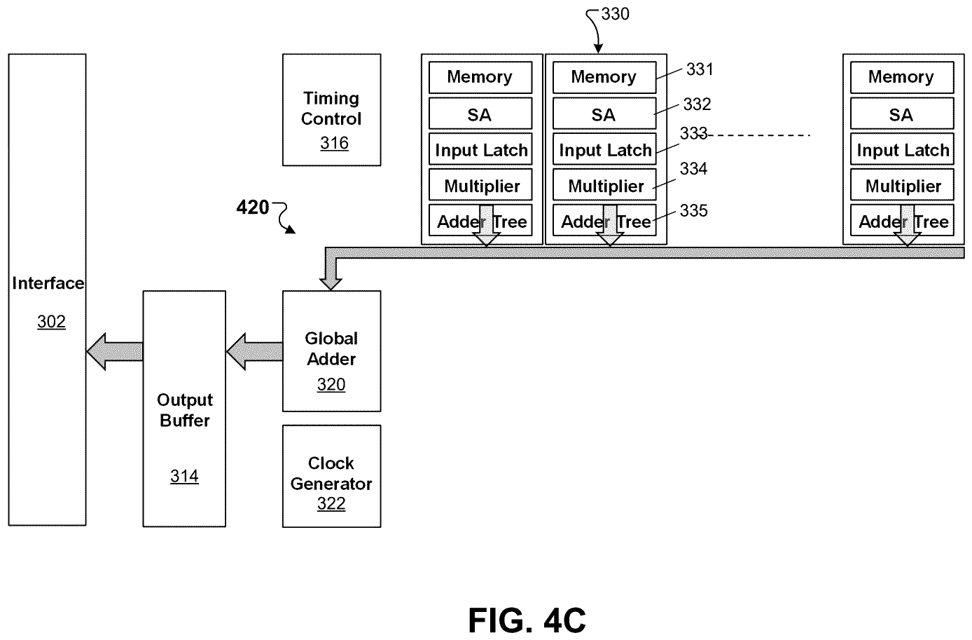

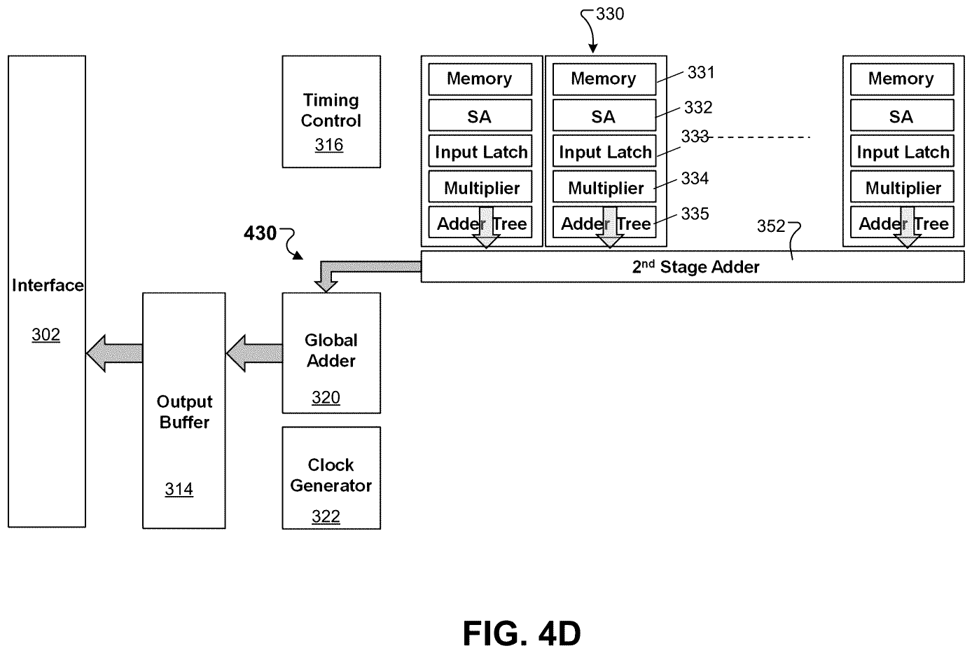

The memory device 200 can be configured as an IMC or CIM device for implementing one or more computing operations or functions, e.g., an MAC operation. The memory device 200 can store weight data and/or embedding data in the memory banks 210 for the computing operation or function. As illustrated with further details in FIG. 3A-4D, the memory device 200, e.g., the controller 220, can additionally include a timing control circuit 260, a repair control circuit 262, and a global adder 264, and each memory unit can include a memory cell array, an input latch circuit, a multiplier circuit, an internal sense amplifier circuit, and an adder circuit, for example, for performing an MAC operation. The input latch circuit can include one or more latches. The multiplier circuit can include one or more multipliers. The internal sense amplifier circuit can include one or more sense amplifiers.

For example, the input latch circuit can be configured to store input data. The internal sense amplifier circuit can read the stored weight and/or embedding data from the memory cell array while the memory device 200 executes the MAC operation. An internal sense amplifier can be different from the sense amplifier 250 that is external to the memory unit or memory bank 210. The internal sense amplifier can have a smaller size than the sense amplifier 250. The multiplier circuit can be configured to multiple respective weights by the input data to obtain multiplication results. The adder circuit can be configured to add the multiplication results to obtain a sum.

The timing control circuit 260 can be configured to arrange timing for operations during executing the computing operation in each memory unit or each memory bank. The timing control circuit 260 can be coupled to the clock generator 241 and the state machine 244. The repair control circuit 262 can receive input data from the host device, and can remap a corresponding portion of the input data to a redundancy region in the input latch circuit of a memory bank 210, in response to a determination that a designated region for storing the corresponding portion of the input data in the input latch circuit is damaged and/or a designated region for storing weight data in a corresponding memory bank is damaged. The repair control circuit 262 can be included in the state machine 244 or be externally coupled to the state machine 244. The global adder 264 can be configured to generate a computing result or a result of the MAC operation based on respective sums obtained from adder circuits of one or more memory units or banks 210 executing the MAC operation. The global adder 264 can be coupled to the memory bank(s) 210 and the output buffer 254.

FIG. 3A is a schematic diagram illustrating an example of a memory device 300 having a global adder 320 for a plurality of memory unit 330. The memory device 300 can be, e.g., the memory device 110 of FIG. 1 or the memory device 200 of FIG. 2. The memory device 300 can include a group of memory banks 308. Each memory bank 308 can include a group of memory units 330, e.g., a row of memory units 330. The memory bank 308 can be, e.g., the memory bank 132 of FIG. 1 or the memory bank 210 of FIG. 2. The memory units 330 can be arranged in an array. The memory device 300 can be configured to perform an MAC operation in the memory units 330. A memory unit 330 can be referred to as an MAC tile. The memory unit 330 can a memory cell array such as a NOR memory cell array.

In some implementations, e.g., as illustrated in FIG. 3A, a memory unit 330 includes a memory cell array 331, one or more internal sense amplifier (SA) circuits 332 (that each can include one or more internal sense amplifiers), one or more input latch circuits 333 (that each can include one or more input latches), one or more multiplier circuits 334 (that each can include one or more multipliers), and an adder tree (or adder circuit) 335. The memory cell array 331 includes memory cells coupled to word lines and bit lines. Weights for a model (e.g., an ML or AI model) can be stored in memory cells coupled to one or more corresponding word lines. An internal SA in the internal SA circuit 332 can be different from the sense amplifier 250 of FIG. 2. The internal SA can be coupled to a group (e.g., a column) of memory cells coupled to a corresponding word line and configured to read data (e.g., weight data) stored in the column of memory cells. An input latch circuit 333 can be configured to store input data (e.g., input vector information). Each input latch can store a bit. Each multiplier circuit 334 is coupled to a corresponding input latch circuit 333 and configured to multiple respective weights by the input data to obtain multiplication results. The adder circuit 335 can be configured to add the multiplication results to obtain a sum.

As illustrated in FIG. 3A, the memory device 300 includes a controller (or circuitry) 301 coupled to the plurality of memory units 330, or the plurality of memory banks 308. The controller 301 can be configured for execution of a computing instruction on input data in one or more memory banks 308, e.g., a single bank operation, a multi-bank operation, or all bank operation, e.g., as illustrated with further details in FIG. 8D.

The controller 301 can be similar to, or same as, the controller 112 of FIG. 1 or the controller 220 of FIG. 2. The controller 301 can include at least one interface 302 (e.g., the interface 114 of FIG. 1 or the interface 230 of FIG. 2) and a control circuitry 304 (e.g., the control circuitry 116 of FIG. 1). The control circuitry 304 is coupled between the at least one interface 302 and the plurality of memory units 330 or the memory banks 308. The at least one interface 302 can be configured to receive the input data, e.g., from a host device such as the host device 120 of FIG. 1, and output the computing result, e.g., to the host device. As noted above, the at least one interface 302 can include one of Serial Peripheral Interface (SPI) protocol, Queued Serial Peripheral Interface (QPI) protocol, or Octal Peripheral Interface (OPI) protocol. In some implementations, the at least one interface 302 can include: a first interface configured according to an LPDDR protocol and a second interface configured according to one of a SPI protocol, a QPI protocol, or an OPI protocol.

The control circuitry 304 can be configured to perform at least one of: programming respective stored data in the one or more memory banks 308 or memory units 330, transferring the input data to the one or more memory banks 308 or memory units 330, executing the computing instruction on the input data and the respective stored data in the one or more memory banks 308 or memory units 330, or outputting the computing result to the at least one interface 302.

In some implementations, e.g., as illustrated in FIG. 3A, the control circuitry 304 includes an input buffer 312 and an output buffer 314 (e.g., the output buffer 254 of FIG. 2). The input buffer 312 is configured to store the input data (e.g., input vector or matrix data) before transferring the input data to the one or more memory banks 308 or memory units 330. The input buffer 312 can include an SRAM, a register, or any other volatile memory. The output buffer 314 is configured to store output data (e.g., a computing result of MAC operation) before outputting the computing result to the at least one interface 302. The output buffer 314 can include an SRAM, a register, or any other volatile memory. Similar to the controller 220 of FIG. 2, the controller 301 can include one or more other components, e.g., an address generator such as the address generator 236 of FIG. 2 and/or a state machine such as the state machine 244 of FIG. 2.

In some implementations, e.g., as illustrated in FIG. 3A, the control circuitry 304 includes a repair control circuit 318 (e.g., the repair control circuit 262 of FIG. 2) configured to: in response to a determination that a designated region for storing input data in the input latch circuit 333 of a memory unit 330 is damaged or has defects, remap the input data to a redundancy region in the input latch circuit 333 of the memory unit 330. In some cases, in response to a determination that a designated region for storing weight or embedding data in a memory unit 330 is damaged or has defects, the repair control circuit 318 can remap weight and/or embedding data from the host device to a redundancy region in the memory unit 330, e.g., as illustrated with further details in FIG. 10C.

In some implementations, e.g., as illustrated in FIG. 3A, the control circuitry 304 includes a clock generator 322 (e.g., the clock generator 241 of FIG. 2) configured to generate a clock signal for an internal MAC operation, e.g., for each of the one or more memory banks 308 or memory units 330 executing the computing operation. The control circuitry 304 can also include a timing control circuit 316 (e.g., the timing control circuit 260 of FIG. 2) configured to arrange timing for operations during executing the computing operation in each of the one or more memory banks 308 or memory units 330. The operations can include two or more of: an operation of the one or more internal sense amplifier circuits 332, an operation of the one or more input latch circuits 333, an operation of the one or more multiplier circuits 334, and an operation of the adder circuit 335.

In some implementations, e.g., as illustrated in FIG. 3A, the control circuitry 304 includes a global adder 320 (e.g., the global adder 264 of FIG. 2) configured to generate a computing result or a result of the MAC operation based on respective sums obtained from adder circuits 335 of one or more memory units 330 executing the MAC operation.

For example, e.g., as illustrated in FIG. 8A, an MAC operation includes multiplying a column of weights with N weight values in a matrix (MxN) with a vector with N vector values to get N multiplication results by multiplier circuits 334 in corresponding memory units 330 and adding the N multiplication results by adder circuits 335 in the corresponding memory units 330 and the global adder 320 to obtain a single MAC result in the global adder 320. The column of weights with N weight values can be stored respectively in the corresponding memory units 330, where each memory unit 330 stores respective weight values of the N weight values. The control circuitry 304 can transfer a corresponding portion of the input vector in the one or more input latch circuits 333 of each memory unit 330. For example, each memory unit 330 stores P weight values in the memory cell array 331, where P can be an integer such as 5, 10, or any suitable number. The number of corresponding memory units can be an integer closet and no smaller than N/P. For example, if N is 100 and P is 10, the number of corresponding memory devices can be 10. If N is 100, and P is 12, and the number of corresponding memory devices can be 9>100/12.

If the P weight values are stored in memory cells coupled to a word line, the one or more input latch circuits 333 can store P vector values of the input vector. The one or more internal sense amplifier circuits 332 can read the stored P weight values from the memory cell array 331, and the one or more multiple circuits 334 can multiple the P weight values by the P vector values to get P multiplication results, and the adder circuit 335 can add the P multiplication results to get a sum for the memory unit 330. Then the global adder 320 can add sums from the adder circuits 335 of the corresponding memory units 330 to get the single MAC result, that is, a result of multiplying N weight values by N vector value.

If the P weight values are stored in memory cells coupled to conductive lines (e.g., bit lines), one or more conductive lines are coupled to a corresponding internal sense amplifier, a corresponding input latch circuit 333, and a corresponding multiplier 334. Multiplying the P weight values and the P vector values can be achieved by two or more corresponding internal sense amplifier circuits 332, two or more input latch circuits 333, and two or more corresponding multiplier circuits 334. The adder circuit 335 can add all the multiplication results from the two or more corresponding multiplier circuits 334 to get a sum of the multiplication results of multiplying the P weight values and the P vector values. Then, the global adder 320 can add sums from the adder circuits 335 of the corresponding memory units 330 to get the single MAC result, that is, a result of multiplying N weight values by N vector value.

FIG. 3B is a schematic diagram illustrating another example of a memory device 350 having a global adder 320 and secondary stage adders 352 for a plurality of memory units 330. The memory device 350 can be similar to the memory device 300 of FIG. 3A, except that the memory device 350 includes two or more secondary stage adders 352. The memory device 350 can be configured to be an IMC or CIM device.

Each secondary stage adder 352 can be coupled to corresponding memory units 330 and configured to add respective sums from adder circuits of the corresponding memory units 330 to obtain a corresponding stage sum. For example, each secondary stage adder 352 can be coupled to a memory bank 308 that can include a row of memory units 330. The global adder 320 is configured to generate an MAC result based on corresponding stage sums from the two or more secondary stage adders 352. For example, the MAC operation can be executed on 100 memory units 330 or 5 memory banks 308. There can be 5 secondary stage adders 352, each coupled to a memory bank 308 or 20 memory units 330. Each secondary stage adder 352 can get a stage sum from the memory bank 308 or the corresponding 20 memory units 330, and the global adder 320 can get a total sum from the stage sums of the 5 secondary stage adders 352.

In some implementations, the memory device 350 can include multiple stage adders. For example, the memory device 350 can include a plurality of secondary stage adders 352 and one or more third stage adders (not shown). Each third stage adder can be coupled to two or more secondary stage adders 352 and configured to obtain a third stage sum from the two or more secondary stage adders 352. The global adder 320 can then generate a total sum by adding third stage sums from the one or more third stage adders. In one example, the MAC operation can be executed on 100 memory units 330. There can be 10 secondary stage adders 352 each coupled to 10 memory units 330. There can be 2 third stage adders each coupled to 5 secondary stage adders 352, and the global adder 320 can be coupled to the 2 third stage adders.

In some implementations, as illustrated in FIG. 8A, the data matrix includes M×N weights. An MAC operation as noted above can calculate the sum of the multiplication of a row of N weights by the input vector with N vector values to obtain a single MAC result. The MAC operation can be repeated for other rows of weights to obtain other MAC results. The final MAC result can be a vector including M MAC results, e.g., as illustrated in FIG. 8A. The final MAC result (e.g., M individual results) for computing MAC of the data matrix M×N and the input vector 1×N can be stored in the output buffer 314 that can output the final MAC result to the host device through the interface 302.

Similarly, the memory device can perform MAC of a first data matrix M×N and a second data matrix N×M, by repeating the MAC operation in the memory device as noted above (e.g., the MAC operation of a vector multiplying a matrix). The second data matrix N×M can be considered as M groups of 1×N vectors. The final MAC result can be an M×M matrix. The final MAC result can be stored in the output buffer 314 that can output the final MAC result to the host device through the interface 302.

FIGS. 4A-4D are schematic diagrams illustrating data input paths and data output paths between a host device and a memory device. The host device can be, e.g., the host device 120 of FIG. 1, and the memory device can be, e.g., the memory device 110 of FIG. 1, the memory device 200 of FIG. 2, the memory device 300 of FIG. 3A, or the memory device 350 of FIG. 3B.

FIG. 4A is a schematic diagram illustrating an example data input path 400 from the host device to the memory device. The data input path 400 can include a communication path between the host device and the memory device and a communication bus or line within the memory device. Along the data input path 400, an interface 302 of the memory device receives input data (e.g., vector data) from the host device according to a protocol, e.g., SPI, QPI, QPI, or LPDDR, and transfers the input data to an input buffer 312 that stores the input data. The memory device can load the input data stored in the input buffer 312 to input latch circuit 333 of corresponding memory units 330. For example, the memory device can load a corresponding portion of the input data from the input buffer to an input latch circuit 333 of each of the corresponding memory units 330 via the communication bus in the memory device, along the data input path 400.

FIG. 4B is a schematic diagram illustrating another example data input path 410 from the host device to the memory device. The data input path 410 is similar to the data input path 400 of FIG. 4A, except that, instead of directly transferring the input data to the corresponding memory units 330, the input data is first transferred to a repair control circuit 318 of the memory device. As noted above, the repair control circuit 318 can remap a corresponding portion of the input data to a redundancy region in an input latch circuit 333 of a memory unit 330, in response to a determination that a designated region for storing the corresponding portion of the input data in the input latch circuit 333 is damaged.

FIG. 4C is a schematic diagram illustrating an example data output path 420 from the memory device to the host device. If the memory device includes a global adder 320, without secondary stage adders, e.g., the memory device 300 of FIG. 3A, sums obtained by adder circuits 335 in the corresponding memory units 330 can be transferred along the data output path 420 to the global adder 320. The global adder 320 generates a single MAC result based on the sums obtained by the adder circuits 335, e.g., by adding the sums together. The single MAC result can be sent to an output buffer 314 that can store the single MAC result. In some cases, as discussed above, by repeating the MAC operation in the memory device, multiple MAC results can be obtained, e.g., as a result of multiplying a data matrix M×N by an input vector 1×N or an input matrix N×M. The output buffer 314 can provide a final MAC result (including one or more MAC results) to the host device through the interface 302. The interface 302 can be configured according to a protocol, e.g., SPI, QPI, QPI, or LPDDR.

FIG. 4D is a schematic diagram illustrating another example data output path 430 from the memory device to the host device. The memory device is similar to, or same as, the memory device 350 of FIG. 3B, including both a global adder 320 and one or more secondary stage adders 352. The data output path 430 is similar to the data output path 420 of FIG. 4C, except that, instead of directly transferring the sums from the adder circuits 335 of the corresponding memory units 330 to the global adder 320, the sums from the adder circuits 335 of the corresponding memory units 330 are first output to the one or more secondary stage adders 352 that generate one or more stage sums based on the sums from the adder circuits 335. Then the one or more secondary stage adders 352 output the one or more stage sums to the global adder 320 that generates an MAC result based on the one or more stage sums. The MAC result can be output by the global adder 320 to the output buffer 314 that stores the MAC result and optionally one or more other MAC results to get a final MAC result. The output buffer 314 can then output the final MAC result to the host device through the interface 302. The interface 302 can be configured according to a protocol, e.g., SPI, QPI, QPI, or LPDDR.

FIG. 5A illustrates a table 500 of example instructions for MAC operation under an interface protocol such as SPI, QPI, or OPI. FIGS. 5B-5D illustrate flow charts of example processes 510, 520, 530 for executing the instructions under the protocol of FIG. 5A. The MAC operation, the example instructions, and/or the example processes can be performed by a memory device, e.g., the memory device 110 of FIG. 1, the memory device 200 of FIG. 2, the memory device 300 of FIG. 3A, or the memory device 350 of FIG. 3B.

As shown in FIGS. 5A, 5B, instructions “Program,” “Read to buffer,” and “Read buffer”, e.g., items 1, 2, 3 in the table 500, can be related to programming data (e.g., weight/embedding data) in a memory bank (e.g., the memory bank 132 of FIG. 1, the memory bank 210 of FIG. 2, or the memory bank 308 of FIG. 3A or 3B) or memory unit (e.g., the memory unit 330 of FIG. 3A, 3B, or 4A-4D). In some examples, embedding data are representations of values or objects like text, images, and audio that machine learning (ML) or artificial intelligence (AI) models or systems and/or computing algorithms (e.g., semantic search algorithms) can use, e.g., to understand complex knowledge.

As illustrated in FIG. 5B, the process 510 include several steps. At step 511, data is programmed in the memory device. The memory device can receive a command from a host device (e.g., the host device 120 of FIG. 1) through an interface (e.g., the interface 114 of FIG. 1, the interface 230 of FIG. 2, or the interface 302 of FIG. 3A, 3B, or 4A-4D). The command can include the data to be programmed, with address information in the memory device. The address information can include a starting address for storing the data in the memory device.

At step 512, the stored data is read into a buffer. The buffer can be a buffer in the memory device (e.g., the output buffer 314 of FIG. 3A, 3B, or 4A-4D), or a buffer external to the memory device.

At step 513, the stored data is read out from the buffer, e.g., by the memory device or by a control circuitry (e.g., the control circuitry 116 of FIG. 1 or 304 of FIG. 3A or 3B). At step 514, it is determined whether the readout data from the buffer matches with the data to be programmed in the memory device, e.g., by the memory device or by the control circuitry. Determining whether the readout data matches with the data to be programmed can include: determining a difference between the readout data and the data to be programmed is smaller than a threshold. The difference can be a number of bits or a percentage of different bits among a total number of bits in the data. The threshold can be, e.g., a threshold for an Error correction code (ECC) circuit to correct or a predetermined threshold.

If the readout data matches with the data to be programmed, the process 510 is done at step 515, which indicates that the data is successfully and accurately stored in the memory device. If the readout data does not match with the data to be programmed, an error message or notification is generated at step 516. The error message or notification can be sent back to the host device through the interface, such that the host device can take action, e.g., resending a command to program the data in the memory device.

As shown in FIGS. 5A, 5C, instructions “Write configuration register” and “Read configuration register”, e.g., items 5, 4 in the table 500, can be related to setting mode registers for the memory device. As illustrated in FIG. 5C, the process 520 include several steps.

At step 521, a configuration register is written. The configuration register can be, e.g., the configuration register 118 of FIG. 1 or a configuration register as described with further details in FIGS. 8B-8E. The configuration register can be configurable by an option code. In some embodiments, an option code includes a number of bits. The memory device can receive a command to write the configuration register, e.g., from the host device. The command can include information of the configuration register, e.g., bits for the option code of the configuration register. The configuration register can be included in the controller of the memory device, e.g., in the control circuitry.

At step 522, the written configuration register is read out, e.g., by the memory device. At step 523, the memory device, e.g., the control circuitry, determines whether the configuration register is correctly written, e.g., by determining whether the readout configuration register matches with the information of the configuration register in the command. If the configuration register is correctly written, the process 520 is done at step 524. If the configuration register is not correctly written, an error message or notification can be generated at step 525. The error message or notification can be sent to the host device through the interface. The host device can take action, e.g., resending a command to write the configuration register in the memory device.

As shown in FIGS. 5A, 5D, instructions “MAC with vector” and “Read MAC result”, e.g., items 6, 7 in the table 500, can be related to executing an MAC operation in the memory device. As illustrated in FIG. 5D, the process 530 include several steps.

At step 531, the memory device executes the MAC operation on input data (e.g., a data vector) using stored weight data in one or more memory units or banks according to a computing instruction, e.g., from the host device. The computing instruction can include a command for the MAC operation, the input data, and address information (e.g., starting address) in the one or more memory units or memory banks that corresponds to weight data stored in the memory devices. As discussed above, the memory device can generate one or more MAC results by a global adder (e.g., the global adder 320 of FIG. 3A, 3B, or 4A-4D). The one or more MAC results can be stored in an output buffer (e.g., the output buffer 254 of FIG. 2 or the output buffer 314 of FIG. 3A, 3B, or 4A-4D). The output buffer can generate a final MAC result based on the one or more MAC results.

At step 532, after the MAC operation is completed, the memory device reads the final MAC result from the output buffer and outputs the final MAC result to the host device through the interface.

FIG. 6A illustrates a table 600 of example instructions for MAC operation under an interface protocol such as LPDDR. FIGS. 6B-6D illustrates flow charts of example processes 610, 620, 630 for executing the instructions under the protocol of FIG. 6A. The MAC operation, the example instructions, and/or the example processes can be performed by a memory device, e.g., the memory device 110 of FIG. 1, the memory device 200 of FIG. 2, the memory device 300 of FIG. 3A, or the memory device 350 of FIG. 3B. The instructions in the table 600 can be similar to the corresponding instructions in the table 500 of FIG. 5A.

As LPDDR is a volatile memory such as DRAM, it cannot store weight data. As discussed above, besides a first interface configured according to LPDDR protocol, the memory device can further include a second interface configured according to another protocol which can be one of SPI, QPI, or OPI protocol. The second interface can be configured to program weight data into one or more memory units or memory banks, e.g., according to step 511 of the process 510 of FIG. 5B. The first interface (e.g., LPDDR protocol) can be configured for performing other instructions, e.g., those listed in the table 600.

For example, as shown in FIGS. 6A, 6B, instructions “Read to buffer” and “Read buffer”, e.g., items 1, 2 in the table 600, can be related to verifying data (e.g., weight/embedding data) in a memory unit (e.g., the memory unit 330 of FIG. 3A, 3B, or 4A-4D) or a memory bank (e.g., the memory bank 132 of FIG. 1, the memory bank 210 of FIG. 2, or the memory bank 308 of FIG. 3A or 3B). As illustrated in FIG. 6B, the process 610 include several steps performed using the first interface, e.g., following programming the weight data using the second interface. The process 610 can be similar to the process 510 of FIG. 5B.

At step 611, the stored data is read into a buffer. The buffer can be a buffer in the memory device (e.g., the output buffer 314 of FIG. 3A, 3B, or 4A-4D). At step 612, the stored data is read out from the buffer, e.g., by the memory device or by a control circuitry (e.g., the control circuitry 116 of FIG. 1 or 304 of FIG. 3A or 3B).

In some implementations, it is determined whether the readout data from the buffer matches with the data to be programmed in the memory device, e.g., by the memory device or by the control circuitry. Determining whether the readout data matches with the data to be programmed can include: determining a difference between the readout data and the data to be programmed is smaller than a threshold. The difference can be a number of bits or a percentage of different bits among a total number of bits in the data. The threshold can be, e.g., a threshold for an Error correction code (ECC) circuit to correct or a predetermined threshold. If the readout data matches with the data to be programmed, the process 610 is done at step 613, which indicates that the data is successfully and accurately stored in the memory device. If the readout data does not match with the data to be programmed, an error message or notification can be generated, e.g., step 516 of FIG. 5B. The error message or notification can be sent back to the host device through the interface, such that the host device can take action, e.g., resending a command to program the data in the memory device using the second interface.

As shown in FIGS. 6A, 6C, instructions “Write mode register” and “Read mode register”, e.g., items 4, 3 in the table 600, can be related to setting mode registers for the memory device. The process 620 can be similar to the process 520 of FIG. 5C. As illustrated in FIG. 6B, the process 620 include several steps.

At step 621, a configuration register is written. The configuration register can be, e.g., the configuration register 118 of FIG. 1 or a configuration register as described with further details in FIGS. 8B-8E. The configuration register can be configurable by an option code. In some embodiments, an option code includes a number of bits. The memory device can receive a command to write the configuration register, e.g., from the host device. The command can include information of the configuration register, e.g., bits for the option code of the configuration register. The configuration register can be included in the controller of the memory device, e.g., in the control circuitry.

At step 622, the written configuration register is read out, e.g., by the memory device. At step 623, the memory device, e.g., the control circuitry, determines whether the configuration register is correctly written, e.g., by determining whether the readout configuration register matches with the information of the configuration register in the command. If the configuration register is correctly written, the process 620 is done at step 624. If the configuration register is not correctly written, an error message or notification can be generated at step 625. The error message or notification can be sent to the host device through the interface. The host device can take action, e.g., resending a command to write the configuration register in the memory device.

As shown in FIGS. 6A, 6D, instructions “Write vector data,” “MAC” and “Read MAC result”, e.g., items 5, 6, 7 in the table 600, can be related to executing an MAC operation in the memory device. The process 630 can be similar to the process 530 of FIG. 5D. As illustrated in FIG. 6D, the process 630 include several steps.

At step 631, the memory device writes input data (e.g., vector data) in one or more memory units or memory banks according to a computing instruction (e.g., from the host device). The computing instruction can include a command for the MAC operation, the input data, and address information (e.g., starting address) in the one or more memory units or memory banks that corresponds to weight data stored in the one or more memory units or memory banks. A corresponding portion of the input data can be written in an input latch circuit (e.g., the input latch circuit 333 of FIG. 3A, 3B or 4A-4D) of each of the one or more memory units or memory banks, e.g., as illustrated in FIG. 4A or 4B.

At step 632, the memory device executes the MAC operation on the input data using the stored weight data in the one or more memory units or memory banks according to the computing instruction. As discussed above, the memory device can generate one or more MAC results by a global adder (e.g., the global adder 320 of FIG. 3A, 3B, or 4A-4D). The one or more MAC results can be stored in an output buffer (e.g., the output buffer 314 of FIG. 3A, 3B, or 4A-4D). The output buffer can generate a final MAC result based on the one or more MAC results.

At step 633, after the MAC operation is completed, the memory device reads the final MAC result from the output buffer and outputs the final MAC result to the host device through the interface. The process 630 ends at step 634.

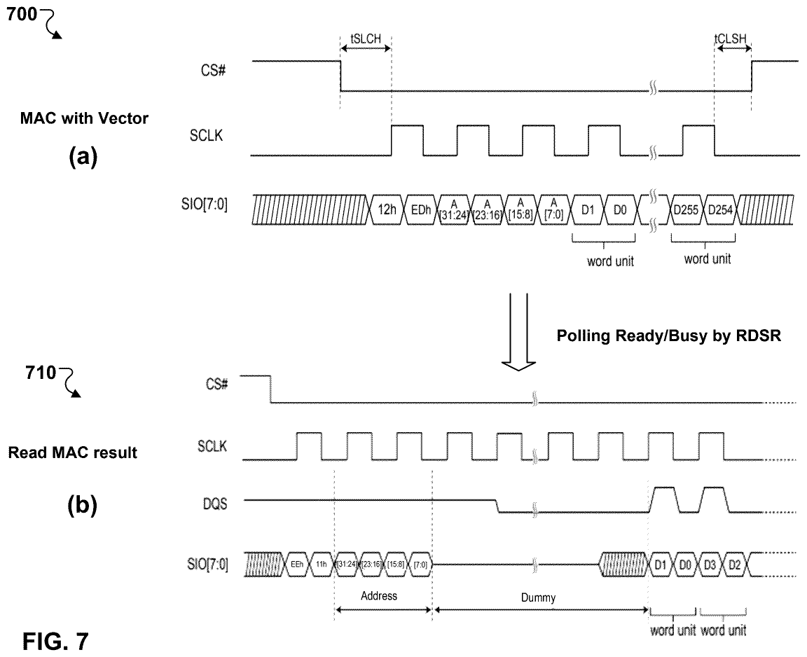

FIG. 7 shows example timing diagrams for performing an MAC operation through an interface according to a protocol, including a first timing diagram 700 showing receiving a command for MAC operation with input data (a), and a second timing diagram 710 showing reading out the MAC result (b). The protocol can be OPI protocol. Table 1 shows example MAC related instructions and the protocol.

TABLE 1
MAC related instructions and Protocol

| | | | | | |
|---|---|---|---|---|---|
| | | | Option/ | | |
| Instruction | CMD | ADDR | Dummy | DATA | Note |

| | | | | |
|---|---|---|---|---|
| MAC with | 4-Byte | NA | Vector data (the length depends on | RDSR to ready |
| vector | | | activation dimension defined in | |
| data | | | configuration register | |
| Read | Don't care | Dummy | MAC result (total length depends on | continuous read |
| MAC | | | weight dimension defined in | |
| result | | | configuration register) | |

The instructions can be transmitted from a host device (e.g., the host device 120 of FIG. 1) to a memory device (e.g., the memory device 110 of FIG. 1, the memory device 200 of FIG. 2, the memory device 300 of FIG. 3A, or the memory device 350 of FIG. 3B). As shown in Table 1 and FIG. 7, the instruction “MAC with vector” can be transmitted to the memory device through the interface while the memory device is selected, with CS # pin being at a lower level. The interface can also receive a serial clock signal (SCLK). The instruction can be received using data pins SIO [7:0] of the interface.

As shown in diagram (a) of FIG. 7, the “MAC with vector” instruction includes a command, a starting address, and input data (e.g., vector data). The command can be represented by a command code 12h and EDh. The starting address (ADDR) has a length of 4 Byte, e.g., represented by A [31:24] A [23:16] A [15:8] A [7:0]. The input data can be represented by a number of word units, e.g., D1, D0, . . . . D255, D254. The length of the input data depends on activation dimension defined in a corresponding configuration register, e.g., as illustrated with further details in FIGS. 8A, 8B. For example, the length can be N that is an integer. When the CS signal becomes a higher level from the lower level, the CS signal triggers internal MAC execution.

The host device can send the MAC instruction to the memory device using a read status register (RDSR) command to read a status of the execution of the MAC instruction. When the MAC instruction is completed, the memory device responses to the RDSR command to notify the host device, and then the host device can send a read command to read the MAC result from the memory device. As discussed above, the MAC result can be stored in an output buffer of the memory device.

As shown in diagram (b) of FIG. 7, the instruction “Read MAC result” can be transmitted to the memory device through the interface while the memory device is selected, with CS # pin being at a lower level. The interface can also receive a serial clock signal (SCLK). The instruction can be received using data pins SIO [7:0] of the interface. The instruction includes a command, a starting address, dummy, and output data (e.g., MAC result). The command can be represented by a command code EEh and 11h. The starting address (ADDR) has a length of 4 Byte, e.g., represented by A [31:24] A [23:16] A [15:8] A [7:0], but don't care, as it is read from the output buffer instead of from a memory device. The output data can be represented by a number of word units, e.g., D1, D0, D3, D2, . . . after dummy cycles. A total length of the output data depends on weight dimension defined in a corresponding configuration register, e.g., as illustrated with further details in FIGS. 8A, 8B. For example, the total length can be M that is an integer.

FIG. 8A illustrates an example MAC operation 800, where a weight matrix M×N is multiplied by a data vector 1×N to obtain a result vector 1×M. The MAC operation is performed using the function Σ (Weight*Vector), which includes multiplication operation and adding operation, e.g., as described with respect to FIGS. 3A, 3B. FIGS. 8B-8E illustrate example configuration registers for the MAC operation of FIG. 8A. The MAC operation can be configurable by the configuration registers shown in FIGS. 8B-8E. The configuration registers can be, e.g., the configuration register 118 of FIG. 1, and can be included in a memory device, e.g., the memory device 110 of FIG. 1, the memory device 200 of FIG. 2, the memory device 300 of FIG. 3A, or the memory device 350 of FIG. 3B. The configuration registers can be used in read or write operation, and can be stored in a volatile or non-volatile memory. A configuration register can be configurable by an option code (OP) that can include a number of bits.

For example, each row in the weight matrix M×N has N weight values, which corresponds to a number of vector values N in the data vector. Thus, a length of the N weight values in a row of the weight matrix or the length N of the data vector can be considered as an activation dimension, which can be configured by a corresponding configuration register, e.g., as shown in FIG. 8B.

The weight matrix M×N has M rows and N columns, and the MAC result can include corresponding M results in the result vector. Thus, a size of the M rows in the weight matrix M×N or a length of the result vector can be considered as a weight dimension, which can be configured by a corresponding configuration register, e.g., as shown in FIG. 8B.

As illustrated in FIG. 8C. a configuration register can be configured for an activation format, where an option code OP[2] for the activation format represents sign information of the integer N. In some examples, e.g., as shown in FIG. 8C, OP[2]=1, representing selecting signed; OP[2]=0, representing selecting unsigned. A configuration register can be configured for a weight format, where an option code OP[1:0] represents sign information of the integer M and a number of bits for representing a range of the weight dimension. In some examples, e.g., as shown in FIG. 8C, OP0=1, representing selecting signed, OP0=0, representing selecting unsigned, OP1=1, representing selecting INT8, OP1=0, representing selecting INT4.

In signed integers, the number can be positive or negative. In some implementations, the leftmost bit of a signed integer is the sign bit (0 for positive numbers, 1 for negative numbers). For example, taking 8 bits, the range is-128 to 127. When performing negative number calculations, two's complement can be used to represent negative numbers. Unsigned integers can only represent non-negative numbers, that is, 0 and positive numbers. Taking 8 bits as an example, the range is 0 to 255 because all bits are used to represent numerical values and there is no sign bit. As an example, INT8 indicates a number of bits: 8 bits (1 byte), which corresponds to −128 to 127 for signed range and 0 to 255 for unsigned range. Similarly, INT4 indicates a number of bits: 4 bits (nibble), which corresponds to for −8 to 7 for signed range and 0 to 15 for unsigned range.

In some implementations, a configuration register can be configured to select a number of memory units or memory banks in the memory device for executing a computing instruction (e.g., MAC operation) in parallel. An option code OP[2:0] for the configuration register can specify the number of memory banks. For example, as illustrated in FIG. 8D, OP[2:0] represents one bank operation, OP[2:0]=1 for dual bank operation, OP[2:0]=2 for quad bank operation, OP[2:0]=3 for eight bank operation, and so forth until all bank operation. To have the most MAC throughput, the configuration register can be set to select all bank operation. To have the less power behavior, the configuration register can be set to select one bank operation. When the configuration register is set to select multi-bank not all bank operation, the selected banks or memory units can be assignable in an “MAC with vector” command (e.g., as described in FIG. 5A or 5D) or a “write vector data” command (e.g., as described in FIG. 6A or 6D).

In some implementations, the interface (e.g., the interface 114 of FIG. 1, 302 of FIG. 3A, 3B, or 4A-4D) for the memory device can be switchable. For example, a configuration register can be configured for switching a protocol for the interface between a first interface protocol and a second interface protocol, e.g., as illustrated in FIG. 8E. The first interface protocol can include a Low-Power Double Data Rate (LPDDR) protocol, and the second interface protocol can include one of Serial Peripheral Interface (SPI), Queued Serial Peripheral Interface (QPI), or Octal Peripheral Interface (OPI). An option code OP[0] can be set to select either the first interface protocol or the second interface protocol. In some examples, e.g., as shown in FIG. 8E, OP[0]=0, representing selecting the second interface protocol or SPI/QPI/OPI mode; OP[0]=1, representing selecting the first interface protocol or LPDDR mode. In some implementations, the configuration register can be written through the second interface protocol (e.g., SPI/QPI/OPI) to switch from the second interface protocol (e.g., SPI/QPI/OPI) to the first interface protocol (e.g., LPDDR), or the configuration register can be written through the first interface protocol (e.g., LPDDR) to switch from the first interface protocol (LPDDR) to the second interface protocol (e.g., SPI/QPI/OPI).

In some implementations, the read content from the memory device can be selectable. For example, a configuration register can be configured for a read command to switch a read content between the computing result and the stored data, such that the same read command can be used for selecting the read command using the configuration register. In some examples, e.g., as illustrated in FIG. 8E, an option code OP[1] can be set to select the read content. For example, OP[1]=0, representing selecting to read MAC result (e.g., from the output buffer as described in FIGS. 5A, 5D or FIGS. 6A, 6D); OP[1]=1, representing selecting to read weight/embedding data (e.g., from a memory device as described in FIGS. 5A, 5B or FIGS. 6A, 6B).

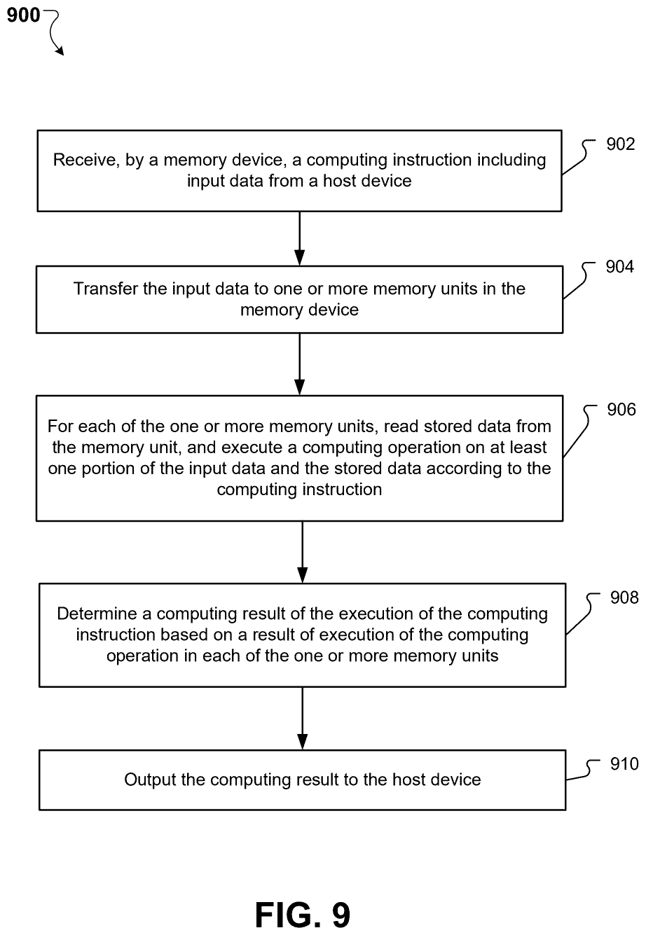

FIG. 9 is a flow chart of an example process 900 of a method for managing a memory device such as an in-memory computing (IMC) device. The process 900 can be performed by the memory device, e.g., the memory device 110 of FIG. 1, the memory device 200 of FIG. 2, the memory device 300 of FIG. 3A, or the memory device 350 of FIG. 3B. The memory device can include one or more memory banks, e.g., the memory bank 132 of FIG. 1, the memory bank 210 of FIG. 2, or the memory bank 308 of FIG. 3A or 3B. Each memory bank can include one or more memory units, e.g., the memory unit 330 of FIG. 3A, 3B, or 4A-4D. The memory unit can include a memory cell array such as a NOR flash memory cell array. The memory device can include a controller (e.g., the controller 112 of FIG. 1 or the controller 220 of FIG. 2) coupled to the memory banks or memory units. The controller can include at least one interface (e.g., the interface 114 of FIG. 1 or the interface 302 of FIG. 3A, 3B, or 4A-4D) and a control circuitry 116 (e.g., the control circuitry 116 of FIG. 1 or 304 of FIG. 3A or 3B).

The process 900 can include several steps. At step 902, a computing instruction is received by the memory device from a host device (e.g., the host device 120 of FIG. 1). The computing instruction can include a command for executing a computing operation (e.g., MAC operation), address information, and input data. The input data can be a data vector or a data matrix, e.g., as illustrated in FIG. 8A. The address information can include a starting address of weight data in a corresponding IMC device for executing the computing instruction. The computing instruction can be, e.g., the “MAC with Vector” instruction as described in diagram (a) of FIG. 7.

At step 904, the input data is transferred to one or more memory units or memory banks in the memory device, e.g., as illustrated in FIG. 4A or 4B. The host device can select the one or more memory banks for a single-bank operation, a multi-bank operation, or an all-bank operation, e.g., by setting a configuration register as illustrated in FIG. 8D. Each of the one or more memory units can include one or more input latch circuits (e.g., the input latch circuit 333 of FIG. 3A, 3B or 4A-4D) that can receive and store a corresponding portion of the input data.

In some implementations, the controller includes a repair control circuit (e.g., the repair control circuit 262 of FIG. 2 or 318 of FIG. 3A, 3B or 4B). The repair control circuit can be configured to: in response to a determination that a designated region for storing a corresponding portion of the input data in an input latch circuit of a memory unit of the one or more memory units is damaged, remap the corresponding portion of the input data to a redundancy region in the input latch circuit of the memory unit.

At step 906, for each of the one or more memory units, stored data (e.g., weight data) is read out from the memory unit (e.g., from a memory cell array such as the memory cell array 331 of FIG. 3A, 3B or 4A-4D). The stored data can be read out by a corresponding internal sense amplifier circuit (e.g., the sense amplifier circuit 332 of FIG. 3A, 3B or 4A-4D). A weight can be stored in one or more memory cells, and a number of the one or more memory cells can be based on a size of the weight and a memory cell type (e.g., SLC, MLC, TLC, QLC, or PLC).

The computing operation is executed on the corresponding portion of the input data and the stored data according to the computing instruction. A multiplier circuit of the memory circuit (e.g., the multiplier circuit 334 of FIG. 3A, 3B or 4A-4D) can multiply the corresponding portion of the input data by the stored data to obtain a plurality of multiplication results. An adder circuit (e.g., the adder circuit 335 of FIG. 3A, 3B or 4A-4D) can add the plurality of multiplication results to obtain a respective sum.

In some implementations, the controller is configured to perform the execution of the computing instruction in the one or more memory units based on the input data. The input data corresponds to a plurality of weights that are respectively stored in the one or more memory units. Each of the one or more memory units can execute the computing operation on a respective portion of the input data and respective weights of the plurality of weights corresponding to the respective portion of the input data. Each of the one or more memory units can execute the computing operation in parallel with each other. In some examples, the input data includes a data vector having a plurality of vector values, a number of the plurality of weights being identical to a number of the plurality of vector values. The multiplier can multiply each of the respective weights by a corresponding vector value of the respective portion of the input data to obtain a corresponding multiplication result of the plurality of multiplication results.

At step 908, a computing result of the execution of the computing instruction is determined based on a result of execution of the computing operation in each of the one or more memory units. The memory device can include a global adder (e.g., the global adder 320 of FIG. 3A, 3B, 4C or 4D) configured to generate the computing result based on respective sums obtained from adder circuits of the one or more memory units.

In some implementations, the memory device further includes one or more secondary stage adders (e.g., the secondary stage adder 352 of FIG. 3B or 4D) coupled to the global adder. Each of the one or more secondary stage adders can be coupled to corresponding memory units (or a corresponding memory bank) and configured to add respective sums from adder circuits of the corresponding memory units to obtain a corresponding stage sum, and the global adder is configured to generate the computing result based on one or more corresponding stage sums from the one or more secondary stage adders.

At step 910, the computing result is output by the memory device to the host device. The controller can include an input buffer (e.g., the input buffer 312 of FIG. 3A, 3B or 4A, or 4B) configured to store the input data before transferring the input data to the one or more memory units, and an output buffer (e.g., the output buffer 254 of FIG. 2 or the output buffer 314 of FIG. 3A, 3B or 4C-4D) configured to store the computing result before outputting the computing result to the host device through the at least one interface.

In some implementations, the controller includes at least one of: a clock generator (e.g., the clock generator 241 of FIG. 2 or the clock generator 322 of FIG. 3A, 3B) configured to generate a clock signal for each of the one or more IMC devices executing the computing operation, or a timing control circuit (e.g., the timing control circuit 260 of FIG. 2 or 316 of FIG. 3A, 3B, 4A-4D) configured to arrange timing for operations during executing the computing operation in each of the one or more memory units. The operations can include two or more of: an operation of the internal sense amplifier circuit, an operation of the input latch circuit, an operation of the multiplier circuit, and an operation of the adder circuit.

In some implementations, the at least one interface is configured to receive the input data from the host device and output the computing result to the host device. The control circuitry is configured to perform at least one of: programming respective stored data in the one or more memory units, transferring the input data to the one or more memory units, executing the computing instruction on the input data and the respective stored data in the one or more memory units, or outputting the computing result to the at least one interface.

In some implementations, the controller includes one or more configuration registers (e.g., the configuration registers 118 of FIG. 1). Each configuration register corresponds to a feature and stores an option code to set up the feature, e.g., as illustrated in FIGS. 8B-8E. The controller can be configured to set the option code for each of the one or more configuration registers. In some cases, the one or more configuration registers are configured to be pre-set by the host device before sending a command for execution of the computing instruction to the memory device.

In some examples, the one or more configuration registers include at least one of: a configuration register for an activation dimension representing a length of the input data (e.g., as illustrated in FIG. 8B), where the option code for the activation dimension represents an integer N; a configuration register for an activation format (e.g., as illustrated in FIG. 8C), where the option code for the activation format represents sign information of the integer N; a configuration register for a weight dimension representing a size of the stored data (e.g., as illustrated in FIG. 8B), where the option code for the weight dimension represents an integer M; a configuration register for a weight format representing sign information of the integer M and a number of bits for representing a range of the weight dimension (e.g., as illustrated in FIG. 8C), or a configuration register for selecting a number of the one or more IMC devices for executing the computing instruction in parallel, where the option code specifies the number of the one or more memory units or memory banks, e.g., as illustrated in FIG. 8D.

In some implementations, the one or more configuration registers include at least one of: a configuration register for switching a protocol for the at least one interface between a first interface protocol and a second interface protocol, or a configuration register for a read command to switch a read content between the computing result and the stored data, e.g., as illustrated in FIG. 8E. In some examples, the first interface protocol includes a Low-Power Double Data Rate (LPDDR) protocol, and the second interface protocol includes one of Serial Peripheral Interface (SPI), Queued Serial Peripheral Interface (QPI), or Octal Peripheral Interface (OPI).

In some implementations, the at least one interface includes an input/output (I/O) interface configured according to an interface protocol that comprises one of Serial Peripheral Interface (SPI) protocol, Queued Serial Peripheral Interface (QPI) protocol, or Octal Peripheral Interface (OPI) protocol.

In some implementations, the at least one interface includes: a first interface configured according to an LPDDR protocol and a second interface configured according to one of a SPI protocol, a QPI protocol, or an OPI protocol. The second interface is configured for programming the respective stored data in the plurality of memory units or memory banks, and the first interface is configured for at least one of setting up one or more corresponding configuration registers, transferring the input data to the memory units, executing the computing instruction on the input data and the respective stored data in the memory units, or outputting the computing result to the first interface.

In some implementations, the controller is configured to receive the computing instruction from the host device. The computing instruction includes a command, the input data, and information corresponding to a starting address of the stored data in each of the memory units. The starting address correspond to a model associated with the computing operation, and the memory units can read the stored data based on the starting address.

In some implementations, the controller is configured to receive a read status command (e.g., RDSR command as illustrated in FIG. 7) from the host device and send a notification message once the execution of the computing instruction is completed. The controller can be configured to receive a read command from the host device and output the computing result to the host device based on the read command.

In some implementations, the memory units in the memory device are configured to perform a particular function corresponding to the computing operation. The memory units can be configured to store weights for multiple models, and weights of each of the multiple models are stored in respective regions of each of the memory units. The weights of each of the multiple models can be updated in the respective regions of each of the memory units.

FIG. 10A is schematic diagram illustrating an example memory unit 1000 in a memory device. The memory unit 1000 can be same as, or similar to, the memory unit 330 of FIG. 3A, 3B, or 4A-4D. The memory device can be same as, or similar to, the memory device 110 of FIG. 1, the memory device 200 of FIG. 2, the memory device 300 of FIG. 3A, or the memory device 350 of FIG. 3B. The memory device can include a plurality of memory units and a circuitry (e.g., the controller 112 of FIG. 1, the controller 220 of FIG. 2, or the controller 301 of FIG. 3A or 3B).

In some implementations, as illustrated in FIG. 10A, the memory unit 1000 includes a memory cell array 1002 and a peripheral circuit 1006 coupled to the memory cell array 1002. The memory cell array 1002 can be same as, or similar to, the memory cell array 331 of FIG. 3A, 3B, or 4A-4D. The memory cell array 1002 includes a plurality of memory cells 1003, and the peripheral circuit 1006 includes a plurality of subcircuits 1005 and an adder circuit 1008 (e.g., the adder circuit 335 of FIG. 3A, 3B, or 4A-4D). The plurality of subcircuits 1005 arc coupled between the memory cell array 1002 and the adder circuit 1008. Each subcircuit 1005 is coupled to one or more memory cells 1003 in the memory cell array 1002 via one or more corresponding bit lines 1004. Each subcircuit 1005 and the one or more memory cells 1003 can form a corresponding column 1010.

In some implementations, as illustrated in FIG. 10B, the peripheral circuit 1006 includes a sense amplifier circuit 1012 (e.g., the SA circuit 332 of FIG. 3A, 3B, or 4A-4D), an input latch circuit 1014 (e.g., the input latch circuit 333 of FIG. 3A, 3B, or 4A-4D), and a multiplier circuit 1016 (e.g., the multiplier circuit 334 of FIG. 3A, 3B, or 4A-4D). The sense amplifier circuit 1012 is coupled to corresponding memory cells 1003 in the memory cell array 1002 via corresponding bit lines 1004.

In some implementations, the circuitry is configured for execution of a computing instruction (e.g., performing an MAC operation) in one or more memory units of the plurality of memory units, e.g., as illustrated in FIGS. 3A-9. The one or more memory units can include the memory unit 1000. The peripheral circuit 1006 of the memory unit 1000 can be configured to perform a computing operation corresponding to the computing instruction. The sense amplifier circuit 1012 can be configured to read weight data from corresponding memory cells 1003 in the memory cell array 1002. The input latch circuit 1014 can be configured to receive input data (e.g., vector data) from the circuitry, e.g., as illustrated in FIG. 4A or 4B. The multiplier circuit 1017 can be coupled to the sense amplifier circuit 1012 and the input latch circuit 1014, and can be configured to multiply the weight data by the input data to obtain a plurality of multiplication results. The adder circuit 1008 can be configured to add the plurality of multiplication results to obtain a sum corresponding to the computing operation.

In some implementations, the input data includes a data vector having a plurality of vector values, and the weight data includes a plurality of weights. In some cases, a number of the plurality of weights is identical to a number of the plurality of vector values. In some other cases, the number of the plurality of weights is different from (e.g., smaller than or greater than) the number of the plurality of vector values. The multiplier circuit 1017 can be configured to multiply each of the plurality of weights by a corresponding vector value of the plurality of vector values to obtain a corresponding multiplication result of the plurality of multiplication results. In some implementations, the circuitry includes a global adder (e.g., the global adder 264 of FIG. 2 or 320 of FIG. 3A-3B or 4C-4D) and/or one or more secondary stage adders (e.g., 352 of FIG. 3B or 4D) configured to generate a computing result for the computing instruction based on one or more sums obtained from one or more adder circuits of the one or more memory units.

In some implementations, e.g., as illustrated in FIG. 10B, the sense amplifier circuit 1012 can include a number of sense amplifiers 1013 (e.g., k sense amplifiers), the input latch circuit 1014 can include a number of input latches 1015 (e.g., l input latches), and the multiplier circuit 1016 can include a number of multipliers 1017 (e.g., m multipliers). k, l, m are integers. In some examples, k, l, m are identical to each other. In some examples, k, l, m are not identical.

A sense amplifier 1013 can be considered as an internal sense amplifier 1013 in the memory unit 1000. For a column 1010, the subcircuit 1005 can include one or more internal sense amplifiers 1013 (e.g., SA0, SA1, SA2, SA3 shown in FIG. 10B), one or more input latches 1015, and one or more multipliers 1017. The one or more internal sense amplifiers 1013 are coupled to one or more memory cells 1003 in the memory cell array 1002 through one or more corresponding bit lines 1004. In some implementations, an internal sense amplifier 1013 is configured to read data (e.g., weight data) from a corresponding memory cell 1003 via a corresponding bit line 1004 and output the read data to a corresponding multiplier 1017. The corresponding multiplier 1017 has a first input coupled to the output of the internal sense amplifier 1013 to receive the read data and a second input coupled to a corresponding input latch 1015 to receive input data (e.g., vector data). The corresponding multiplier 1017 can generate a multiplication result based on the read data and the input data and output the multiplication result to the adder circuit 1008.

In some implementations, a number of the one or more internal sense amplifiers 1013 is identical to a number of the one or more memory cells 1003. In some implementations, a number of the one or more input latches 1015 is identical to the number of the one or more internal sense amplifiers 1013. In some implementations, a number of the one or more multipliers 1017 is identical to the number of the one or more input latches 1015 or the number of the one or more internal sense amplifiers 1013.

In some implementations, different columns 1010 in the memory unit 1000 have a same number of memory cells 1003, a same number of sense amplifiers 1013, a same number of input latches 1015, and/or a same number of multipliers 1017. In some implementations, different columns 1010 in the memory unit 1000 may have different numbers of memory cells 1003, different numbers of sense amplifiers 1013, different numbers of input latches 1015, and/or different number of multipliers 1017.

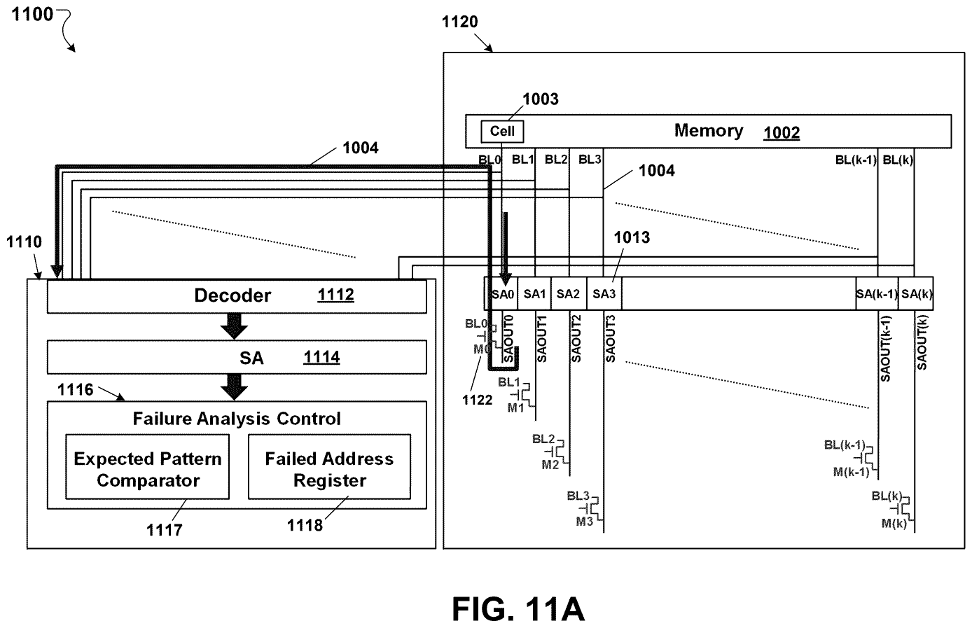

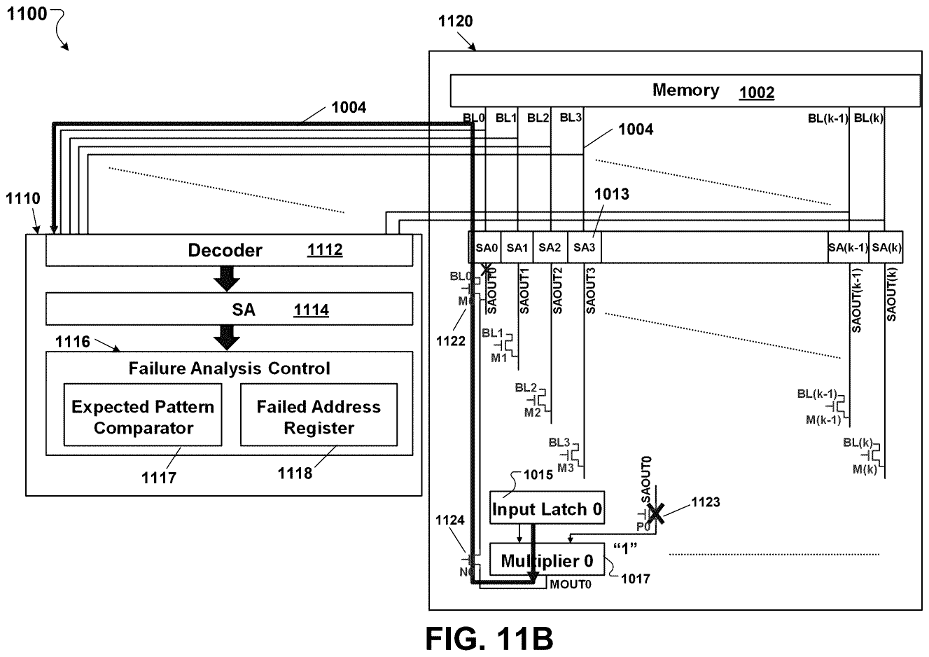

FIG. 10C illustrates an example of repairing a defective column 1010 in the memory unit 1000 of FIGS. 10A-10B. A column 1010 in the memory unit 1000 can be considered or treated to be defective if data stored in at least one memory cell 1003 in the column 1010 or the at least one memory cell 1003 is damaged, or at least one component (such as a sense amplifier 1013, an input latch 1015, or a multiplier 1017) in the subcircuit 1005 in the column 1010 is defective. For example, as illustrated in FIG. 10C, a defective column 1010′ has error occurred in a memory cell 1003′ and in a sense amplifier 1013′. FIGS. 11A-11B provide examples for performing failure analysis in a memory unit with further details.

In response to determining that the column 1010′ is defective (e.g., the at least one memory cell 1003′ or at least part of the subcircuit 1005′ is defective), the circuitry can perform one or more corresponding actions. In some examples, the circuitry can mark the column as a defective column or a subcircuit as a defective subcircuit, and can store a corresponding address for the damaged data (or the memory cell 1003′) or the subcircuit as a failed address in the circuitry.

In some implementations, e.g., as illustrated in FIG. 10C, the circuitry can replace the defective column 1010′ with a redundant column 1020 of the memory unit 1000. The redundant column 1020 can be identical to the defective column 1010′ except that the redundant column 1020 is a blank and healthy column 1010 in the memory unit 1000. A number of redundant memory cells 1003 in the redundant column 1020 can be identical to a number of corresponding memory cells in the defective column 1010′. A redundant subcircuit 1005 in the redundant column 1020 can be identical to the subcircuit 1005′ in the defective column 1010′, e.g., having a same number of sense amplifiers 1013, a same number of input latches 1015, and a same number of multipliers 1017.

In some examples, the circuitry can remap stored data in the corresponding memory cells coupled to the subcircuit 1005′ in the defective column 1010′ to the redundant memory cells 1003 in the redundant column 1020. The circuitry can remap a portion 1050-1 of input data 1050 loaded (or to be loaded) in the one or more latches 1015 of the subcircuit 1005′ to one or more redundant latches 1015 of the redundant subcircuit 1005. The circuitry can also clear the one or more latches 1015 of the subcircuit 1005′ in the defective column 1010′, e.g., by loading a value of “0”. In such a way, when a computation operation is performed in the memory unit 1000, the multipliers 1017 in the defective column 1010′ generate and output a result of “0” to the adder circuit 1008. That is, the defective column 1010′ does not affect a sum result of the adder circuit 1008.

FIGS. 11A-11B illustrate examples of performing failure analysis of a memory unit in a memory device 1100. The memory device 1100 can be same as, or similar to, the memory device 110 of FIG. 1, the memory device 200 of FIG. 2, the memory device 300 of FIG. 3A, or the memory device 350 of FIG. 3B. The memory device 1100 can include a plurality of memory units 1120 and a circuitry 1110 (e.g., the controller 112 of FIG. 1, the controller 220 of FIG. 2, or the controller 301 of FIG. 3A or 3B). A memory unit 1120 of the plurality of memory units 1120 can be same as, or similar to, the memory unit 330 of FIG. 3A, 3B, or 4A-4D or the memory unit 1000 of FIGS. 10A-10C. The circuitry 1110 can be configured to perform failure analysis of the memory unit 1120.

The memory unit 1120 can include a memory cell array 1002 having a plurality of memory cells 1003 (e.g., k memory cells), a plurality of sense amplifiers 1013 (e.g., SA0, SA1, SA2, SA3, . . . , SA(k−1), SA(k)), a plurality of input latches 1015, and/or a plurality of multipliers 1017, where k is an integer. A sense amplifier 1013 in the memory unit 1120 can be referred to as an internal sense amplifier 1013. A memory cell 1003 in the memory cell array 1002 is coupled to a corresponding internal sense amplifier 1013 through a corresponding bit line 1004. The corresponding internal sense amplifier 1013 can read data stored in the memory cell 1003 via the corresponding bit line 1004.

In some implementations, the circuitry 1110 includes a sense amplifier 1114 (e.g., the sense amplifier 250 of FIG. 2) external to the plurality of memory units 1120, which can be referred to an external sense amplifier 1114. The internal sense amplifier 1013 can be different from the external sense amplifier 1114. For example, the internal sense amplifier 1013 can have a smaller size and lower power consumption than the external sense amplifier 1114, and the external sense amplifier 1114 can be operated faster than the internal sense amplifier 1013.

The circuitry 1110 can further include a decoder 1112 (e.g., the Y-Decoder 248 of FIG. 2) coupled between the bit lines 1004 and the external sense amplifier 1114. In some implementations, the external sense amplifier 1114 can directly read data stored in the memory cells 1003 through the bit lines 1004 and the decoder 1112.

In some implementations, the circuitry 1110 further includes a failure analysis controller 1116, which can be included in a state machine (e.g., the state machine 244 of FIG. 2) of the circuitry 1110. The failure analysis controller 1116 can include a comparator 1117 and a register 1118. The comparator 1117 is coupled to the external sense amplifier 1114 and can be configured to compare a result of the external sense amplifier 1114 sensing a detection result transmitted from a memory unit and corresponding reference data stored in the failure analysis controller 1116. For example, if the result of the external sense amplifier 1114 matches the corresponding reference data, the comparator 1117 can determine that a corresponding memory cell and/or a corresponding internal sense amplifier is not defective, or a corresponding input latch and/or a corresponding multiplexer is not defective. If the result of the external sense amplifier 1114 does not match the corresponding reference data, the comparator 1117 can determine that a corresponding memory cell and/or a corresponding internal sense amplifier is defective, or a corresponding input latch and/or a corresponding multiplexer is defective. The failure analysis controller 1116 can further include a failed address register 1118 configured to store a corresponding address for defective data or memory cells 1003 in the memory cell array 1002 or a defective circuit (e.g., a defective sense amplifier 1013, a defective input latch 1015, and/or a defective multiplier 1017) as a failed address.

In some implementations, the memory unit 1120 includes a plurality of transistors 1122 for the plurality of internal sense amplifier 1013. Each transistor 1122 can have a first terminal coupled to an output of a corresponding internal sense amplifier 1013, a second terminal coupled to a corresponding bit line, and a gate terminal configured to receive a gate control signal for turning on or off the transistor 1122. For example, as illustrated in FIG. 11A, the memory unit 1120 includes k internal sense amplifier 1013 (e.g., SA0, SA1, SA2, SA3, . . . , SA(k−1), SA(k)) coupled to corresponding memory cells 1003 in the memory cell array 1002 through k respective bit lines (e.g., BL0, BL1, BL2, BL3, . . . , BL(k−1), BLk) and configured to read data from the corresponding memory cells 1003 to generate and output k corresponding outputs (e.g., SAOUT0, SAOUT1, SAOUT2, SAOUT3, . . . , SAOUT(k−1), SAOUTk) to k transistors 1122 that each are respectively coupled back to the k bit lines 1004 to the circuitry 1110 (e.g., to the external sense amplifier 1114).

As noted above in FIGS. 10A-10B, the memory unit 1120 can include a plurality of columns (e.g., the column 1010 of FIG. 10A or 10B). Each column can include one or more memory cells 1003, one or more internal sense amplifiers 1013, one or more input latches 1015, and one or more multiplier 1017. In operation for performing failure analysis on the column in the memory unit 1120, the circuitry 1110 can determine whether at least one memory cell 1003, at least one internal sense amplifier 1013, at least one input latch 1015, and/or at least one multiplier 1017 is damaged or defective. The circuitry 1110 may determine that a column is defective based on a determination of at least one defective memory cell 1003, at least one defective internal sense amplifier 1013 in the column, at least one defective input latch 1015, and/or at least one defective multiplier 1017.

In some implementations, the circuitry 1110 can perform (e.g., sequentially) the failure analysis on the one or more memory cells 1003 and/or one or more internal sense amplifiers 1013 in the column, e.g., as illustrated in FIG. 11A. If a first internal sense amplifier 1013 in the column is healthy (not defective), the circuitry 1110 can move to perform the failure analysis on a second internal sense amplifier 1013 in the column. If the first internal sense amplifier 1013 in the column is defective, the circuitry 1110 can determine the column is a defective column and take one or more corresponding actions, e.g., as noted above. In some implementations, the circuitry 1110 may determine that a column is defective based on a determination of one or more defective memory cells 1003 and/or one or more defective internal sense amplifiers 1013.

In some implementations, e.g., as illustrated in FIG. 11A, an internal sense amplifier 1013 reads data from a corresponding memory cell 1003 through a corresponding bit line 1004 (e.g., BL0) to generate an output (e.g., SAOUT0). The memory unit 1120 can be configured to: receive a gate control signal at the gate terminal of a corresponding transistor 1122 to turn on the transistor 1122 while the internal sense amplifier 1013 reads the data from the corresponding memory cell 1003 via the corresponding bit line 1004, and output the data read from the corresponding memory cell 1003 by the internal sense amplifier 1013 via the corresponding bit line 1004 to the circuitry 1110 (e.g., to the external sense amplifier 1114). The external sense amplifier 1114 can sense the data read from the corresponding memory cell by the internal sense amplifier 1013 to generate a detection result. The failure analysis controller 1116 in the circuitry 1110 can determine whether at least one of the corresponding memory cell 1003 or the internal sense amplifier 1013 is damage or defective based on the detection result.

In some implementations, the circuitry 1110 is configured to perform a failure analysis on the one or more input latches 1015 and/or the one or more multipliers 1017 in the column, e.g., as illustrated in FIG. 11B. A multiplier 1017 (e.g., Multiplier 0) can include a first input for receiving a sensing output (e.g., SAOUT0) from a corresponding internal sense amplifier 1013 (e.g., SA0), a second input for receiving input data from a corresponding input latch 1015 (e.g., Input Latch 0), and generate a multiplication result (e.g., MOUT0) based on the input data and the sensing output.

In some implementations, for each multiplier 1017 in the memory unit 1120, the memory unit 1120 includes a connection transistor 1123 coupled between the multiplier 1017 and a corresponding internal sense amplifier 1013. The connection transistor 1123 can have a first terminal coupled to an output of the corresponding internal sense amplifier 1013, a second terminal coupled to the first input of the multiplier 1017, and a gate terminal for receiving a gate control signal to turn on or off the connection transistor 1123. In some implementations, the memory unit 1120 includes a transistor 1124 having a first terminal coupled to the output of the multiplier 1017, a second terminal coupled to a corresponding bit line 1004 coupled to the corresponding internal sense amplifier 1013, and a gate terminal for receiving a gate control signal to turn on or off the transistor 1124. In some implementations, the transistor 1124 is directly coupled to the corresponding bit line 1004. In some implementations, the transistor 1124 is coupled to the corresponding bit line 1004 through the transistor 1122, e.g., the transistor 1124 can be coupled to the second terminal of the transistor 1122.

In operation for performing a failure analysis on a multiplier 1017 and/or a corresponding input latch 1015 in a column, the memory unit 1120 can be configured to turn off the connection transistor 1123 such that the multiplier 1017 receives a constant value (e.g., “1”) from the connection transistor 1123, and the output of the multiplier 1017 can be just based on input data from the corresponding input latch 1015. The memory unit 1120 can turn on the transistor 1124 and the transistor 1122 to output the output of the multiplier 1017 that is based on the input data from the corresponding input latch 1015 via the corresponding bit line 1004 to the external sense amplifier 1114 for determining whether at least one of the corresponding input latch 1015 or the multiplier 1017 is defective.

In operation for performing a computation operation, the memory unit 1120 can be configured to turn on the connection transistor 1123 and turn off the transistor 1122 and the transistor 1124, such that the multiplier 1017 receives data read from the corresponding memory cell 1003 by the corresponding sense amplifier 1013 and input data from the corresponding input latch 1015 and generate a multiplication result based on the data read from the corresponding memory cell and the input data. The multiplication result can be output to an adder circuit (e.g., the adder circuit 1008 of FIG. 10A or 10B) in the memory unit 1120.

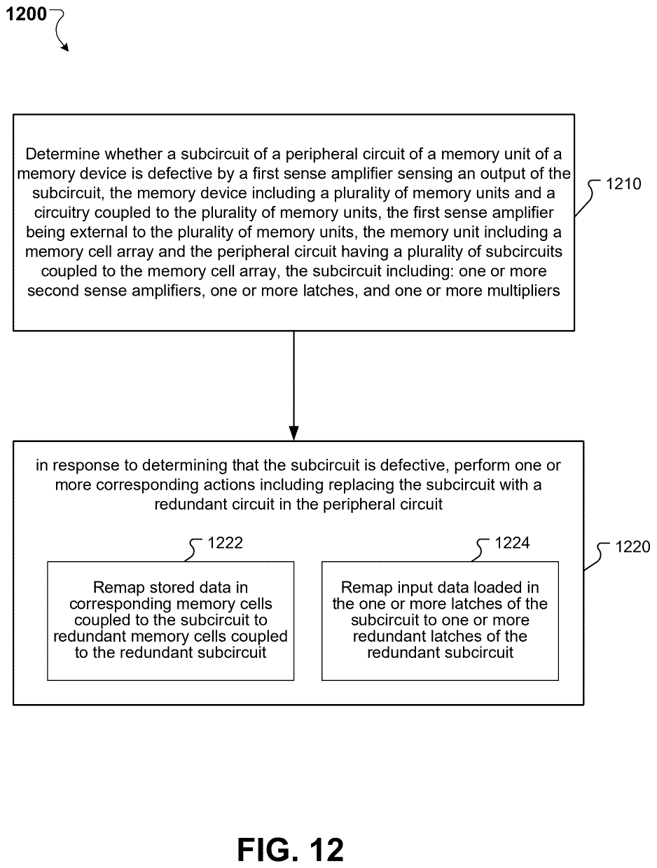

FIG. 12 is a flow chart of an example process 1200 of a method for managing failures of a memory device. The memory device can be, e.g., the memory device 110 of FIG. 1, the memory device 200 of FIG. 2, the memory device 300 of FIG. 3A, the memory device 350 of FIG. 3B, or the memory device 1100 of FIG. 11A or 11B. The memory device can include a plurality of memory units and a circuitry coupled to the plurality of memory units. The circuitry can be, e.g., the controller 112 of FIG. 1, the controller 220 of FIG. 2, or the controller 301 of FIG. 3A or 3B, or the circuitry 1110 of FIG. 11A or 11B. The process 1200 can be performed by the memory device.

A memory unit of the plurality of memory units can be same as, or similar to, the memory unit 330 of FIG. 3A, 3B, or 4A-4D, the memory unit 1000 of FIGS. 10A-10C, or the memory unit 1120 of FIG. 11A or 11B. The memory unit can include a memory cell array (e.g., the memory cell array 331 of FIGS. 3A-4D, or the memory cell array 1002 of FIGS. 10A-10C, FIG. 11A or 11B) and a peripheral circuit (e.g., the peripheral circuit 1006 of FIG. 10A). The memory cell array 1002 can include a plurality of memory cells (e.g., the memory cells 1003 of FIGS. 10A-10C, FIG. 11A or 11B). The peripheral circuit can include a plurality of subcircuits (e.g., the subcircuit 1005 of FIGS. 10A-10C).

At 1210, the memory device (e.g., the circuitry) determines whether a subcircuit of the peripheral circuit of the memory unit of the memory device is defective by a first sense amplifier sensing an output of the subcircuit. The first sense amplifier can be, e.g., the sense amplifier 250 of FIG. 2, or the external sense amplifier 1114 of FIG. 11A or 11B. The first sense amplifier is external to the plurality of memory units. The subcircuit can include: one or more second sense amplifiers (e.g., the internal sense amplifier 1013 of FIGS. 10A-10C, FIG. 11A or 11B), one or more latches (e.g., the input latch 1015 of FIG. 10B, 10C, 11A or 11B), and one or more multipliers (e.g., the multiplier 1017 of FIG. 10B, 10C, 11A, or 11B).

At 1220, in response to determining that the subcircuit is defective, the memory device (or the circuitry) performs one or more corresponding actions. The one or more corresponding actions can include replacing the subcircuit (e.g., the subcircuit 1005′ of FIG. 10C) with a redundant subcircuit (e.g., the subcircuit 1005 of FIG. 10C) in the peripheral circuit.

In some implementations, the one or more corresponding actions include at least one of: remapping stored data in corresponding memory cells coupled to the subcircuit to redundant memory cells coupled to the redundant subcircuit (1222), or remapping input data loaded in the one or more latches of the subcircuit to one or more redundant latches of the redundant subcircuit (1224), e.g., as illustrated in FIG. 10B.

In some implementations, the peripheral circuit further includes an adder circuit coupled to the plurality of subcircuits. The adder circuit can be, e.g., the adder circuit 335 of FIG. 3A to 4D or the adder circuit 1008 of FIG. 10A-10C, 11A, or 11B. The one or more corresponding actions can further include: in response to determining that the subcircuit is defective, clearing the one or more latches of the subcircuit with a value of “0”, e.g., as illustrated in FIG. 10B.

In some implementations, the circuitry includes a failure analysis controller (e.g., the failure analysis controller 1116 of FIG. 11A or 11B). The failure analysis controller includes: a comparator (e.g., the comparator 1117 of FIG. 11A or 11B) coupled to the first sense amplifier and configured to compare the result of the first sense amplifier sensing the detection result transmitted from the subcircuit and corresponding reference data stored in the failure analysis controller. The failure analysis controller can also include: a register configured to store a corresponding address for defective data in the memory cell array or a defective subcircuit as a failed address.

In some implementations, the subcircuit includes one or more first transistors (e.g., the transistors 1122 of FIG. 11A or 11B). Each of the one or more first transistors is coupled between a second sense amplifier of the one or more second sense amplifiers and a bit line that is coupled to the first sense amplifier. The second sense amplifier is configured to read data from a memory cell via the bit line and output the data read by the second sense amplifier through the first transistor via the bit line to the first sense amplifier. The circuitry is configured to: determine whether the second sense amplifier of the subcircuit is defective based on a result of the first sense amplifier sensing the data read from the memory cell by the second sense amplifier.

In some implementations, the subcircuit further includes one or more second transistors (e.g., the transistor 1124 of FIG. 11B). Each of the one or more second transistors is coupled between a corresponding multiplier of the one or more multipliers and a corresponding bit line. The subcircuit is configured to: turn off a connection between the corresponding multiplier and a corresponding second sense amplifier, and output, by the corresponding multiplier, an output based on input data from a corresponding latch via the corresponding bit line to the first sense amplifier. The circuitry is configured to determine whether at least one of the corresponding latch or the corresponding multiplier is defective based on a result of the first sense amplifier sensing the output by the corresponding multiplier.

In some implementations, the subcircuit further includes a connection transistor (e.g., the connection transistor 1123 of FIG. 11B) having a first terminal coupled to an output of the corresponding second sense amplifier, a second terminal coupled to a first input of the corresponding multiplier, and a connection gate terminal. The output of the corresponding sense amplifier is coupled to a first terminal of a corresponding first transistor, and the corresponding bit line is coupled to a second terminal of the corresponding first transistor. The second transistor comprises a first terminal coupled to an output of the corresponding multiplier, and a second terminal coupled to the first terminal of the corresponding first transistor.

In some implementations, the subcircuit is configured to: turn off the connection transistor and the second transistor, and turn on the corresponding first transistor to output data read from a corresponding memory cell by the corresponding second sense amplifier via the corresponding bit line to the first sense amplifier for determining whether the corresponding second sense amplifier is defective, and turn off the connection transistor, and turn on the second transistor and the corresponding first transistor to output the output based on the input data from the corresponding latch via the corresponding bit line to the first sense amplifier for determining whether at least one of the corresponding input latch or the multiplier is defective.

In some implementations, the subcircuit is configured to turn on the connection transistor, and turn off the first transistor and the second transistor, such that the multiplier receives the data read from the corresponding memory cell by the corresponding sense amplifier and the input data from the corresponding latch and generate a multiplication result based on the data read from the corresponding memory cell and the input data.

In some implementations, the peripheral circuit includes a sense amplifier circuit (e.g., the SA circuit 332 of FIGS. 3A to 4D or the SA circuit 1012 of FIG. 10B or 10C) coupled to the memory cell array, and the sense amplifier circuit can include a plurality of second sense amplifiers in the plurality of subcircuits. The peripheral circuit can include an input latch circuit (e.g., the input latch circuit 333 of FIGS. 3A to 4D, or 1014 of FIG. 10B or 10C), and the input latch circuit can include plurality of input latches in the plurality of subcircuits. The peripheral circuit can include a multiplier circuit (e.g., the multiplier circuit 334 of FIGS. 3A to 4D or 1016 of FIG. 10B or 10C) coupled to the sense amplifier circuit and the input latch circuit. The multiplier circuit can include a plurality of multipliers in the plurality of subcircuits. The peripheral circuit can also include an adder circuit (e.g., the adder circuit 335 of FIG. 3A to 4D or the adder circuit 1008 of FIG. 10A-10C, 11A, or 11B) coupled to the multiplier circuit.

In some implementations, the circuitry is configured for execution of a computing instruction in one or more memory units of the plurality of memory units, and the peripheral circuit of the memory unit is configured to perform a computing operation corresponding to the computing instruction. The memory device can be a NOR flash memory device, and the computing operation can include a Multiply-Accumulate (MAC) operation.

The sense amplifier circuit is configured to read weight data from corresponding memory cells in the memory cell array, the input latch circuit is configured to receive input data from the circuitry, the multiplier circuit is configured to multiply the weight data by the input data to obtain a plurality of multiplication results, and the adder circuit configured to add the plurality of multiplication results to obtain a sum corresponding to the computing operation.

In some implementations, the input data comprises a data vector having a plurality of vector values, and the weight data comprises a plurality of weights. A number of the plurality of weights can be identical to or different from a number of the plurality of vector values. The multiplier circuit can be configured to multiply each of the plurality of weights by a corresponding vector value of the plurality of vector values to obtain a corresponding multiplication result of the plurality of multiplication results.

In some implementations, the circuitry includes a global adder (e.g., the global adder 264 of FIG. 2 or 320 of FIG. 3A-3B or 4C-4D) and/or one or more secondary stage adders (e.g., the secondary stage adders 352 of FIG. 3B or 4D) configured to generate a computing result for the computing instruction based on one or more sums obtained from one or more adder circuits of the one or more memory units.

The disclosed and other examples can be implemented as one or more computer program products, for example, one or more modules of computer program instructions encoded on a computer readable medium for execution by, or to control the operation of, data processing apparatus. The computer readable medium can be a machine-readable storage device, a machine-readable storage substrate, a memory device, or a combination of one or more them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A system may encompass all apparatus, devices, and machines for processing data, including by way of example a programmable processor, a computer, or multiple processors or computers. A system can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed for execution on one computer or on multiple computers that are located at one site or distributed across multiple sites and interconnected by a communications network.

The processes and logic flows described in this document can be performed by one or more programmable processors executing one or more computer programs to perform the functions described herein. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer can include a processor for performing instructions and one or more memory devices for storing instructions and data. Generally, a computer can also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data can include all forms of nonvolatile memory, media and memory devices, including by way of example semiconductor memory devices, e.g., EPROM, EEPROM, and flash memory devices; magnetic disks. The processor and the memory can be supplemented by, or incorporated in, special purpose logic circuitry.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A memory device, comprising:
a plurality of memory units; and
a circuitry coupled to the plurality of memory units,
wherein a memory unit of the plurality of memory units comprises:
a memory cell array comprising memory cells; and
a peripheral circuit comprising a plurality of subcircuits,
wherein a subcircuit of the plurality of subcircuits is configured to read data from a corresponding memory cell via a corresponding bit line and output a detection result via the corresponding bit line to a sense amplifier in the circuitry, the sense amplifier being external to the memory unit, and
wherein the circuitry is configured to:
determine whether at least one of the corresponding memory cell or the subcircuit is defective based on a result of the sense amplifier sensing the detection result from the subcircuit, and
in response to determining that the at least one of the corresponding memory cell or the subcircuit is defective, perform one or more corresponding actions.

2. The memory device of claim 1, wherein the sense amplifier is a first sense amplifier, and the subcircuit comprises:
one or more second sense amplifiers,
one or more latches, and
one or more multipliers,
wherein a multiplier of the one or more multipliers comprises:
a first input coupled to an output of a corresponding second sense amplifier of the one or more second sense amplifiers and configured to receive the data read from the corresponding memory cell by the corresponding second sense amplifier,
a second input coupled to a corresponding latch of the one or more latches and configured to receive input data from the corresponding latch, and
an output configured to output a multiplication result based on the data read from the corresponding memory cell by the corresponding second sense amplifier and the input data from the corresponding latch.

3. The memory device of claim 2, wherein the subcircuit further comprises a transistor having a first terminal coupled to the output of the corresponding second sense amplifier, a second terminal coupled to the corresponding bit line, and a gate terminal, and
wherein the subcircuit is configured to:
receive a gate control signal at the gate terminal of the transistor to turn on the transistor while the corresponding second sense amplifier reads the data from the corresponding memory cell via the corresponding bit line, and
output the data read from the corresponding memory cell by the corresponding second sense amplifier via the corresponding bit line to the first sense amplifier.

4. The memory device of claim 3, wherein the detection result comprises the data read from the corresponding memory cell by the corresponding second sense amplifier, and
wherein the circuitry is configured to: determine whether at least one of the corresponding memory cell or the corresponding second sense amplifier of the subcircuit is defective based on the data read from the corresponding memory cell by the corresponding second sense amplifier.

5. The memory device of claim 2, wherein the subcircuit further comprises a transistor having a first terminal coupled to the output of the multiplier, a second terminal coupled to the corresponding bit line, and a gate terminal, and
wherein the subcircuit is configured to:
turn off a connection between the first input of the multiplier and the output of the corresponding second sense amplifier, and
output, by the multiplier, an output based on the input data from the corresponding latch.

6. The memory device of claim 5, wherein the detection result comprises the output based on the input data from the corresponding latch, and
wherein the circuitry is configured to determine whether at least one of the corresponding input latch or the multiplier is defective based on the output that is based on the input data from the corresponding latch.

7. The memory device of claim 5, wherein the subcircuit further comprises a connection transistor having a first terminal coupled to the output of the corresponding second sense amplifier, a second terminal coupled to the first input of the multiplier, and a gate terminal, and
wherein the connection transistor is configured to be turned off to turn off the connection between the first input of the multiplier and the output of the corresponding second sense amplifier.

8. The memory device of claim 2, wherein the subcircuit further comprises:
a first transistor having a first terminal coupled to the output of the corresponding second sense amplifier, a second terminal coupled to the corresponding bit line, and a first gate terminal;
a second transistor having a first terminal coupled to the output of the multiplier, a second terminal coupled to the second terminal of the first transistor, and a second gate terminal; and
a connection transistor having a first terminal coupled to the output of the corresponding second sense amplifier, a second terminal coupled to the first input of the multiplier, and a connection gate terminal.

9. The memory device of claim 8, wherein the subcircuit is configured to:
turn off the connection transistor and the second transistor, and turn on the first transistor to output the data read from the corresponding memory cell by the corresponding second sense amplifier via the corresponding bit line to the first sense amplifier for determining whether at least one of the corresponding memory cell or the corresponding sense amplifier is defective, and
turn off the connection transistor, and turn on the second transistor and the first transistor to output an output based on the input data from the corresponding latch via the corresponding bit line to the first sense amplifier for determining whether at least one of the corresponding input latch or the multiplier is defective.

10. The memory device of claim 2, wherein the one or more corresponding actions comprise one or more of:
marking the subcircuit as a defective subcircuit,
storing a corresponding address for the at least one of the corresponding memory cell or the subcircuit as a failed address in the circuitry,
remapping stored data in corresponding memory cells coupled to the subcircuit to redundant memory cells coupled to a redundant subcircuit in the peripheral circuit,
remapping input data loaded in the one or more latches of the subcircuit to one or more redundant latches of the redundant subcircuit, and
clearing the one or more latches of the subcircuit with a value of “0”.

11. The memory device of claim 1, wherein the circuitry comprises a failure analysis controller comprising:
a comparator coupled to the sense amplifier and configured to compare the result of the sense amplifier sensing the detection result transmitted from the subcircuit and corresponding reference data stored in the failure analysis controller; and
a register configured to store a corresponding address for defective data in the memory cell array or a defective subcircuit as a failed address.

12. The memory device of claim 1, wherein the peripheral circuit comprises:
a sense amplifier circuit coupled to the memory cell array, the sense amplifier circuit comprising a plurality of sense amplifiers in the plurality of subcircuits,
an input latch circuit comprising a plurality of input latches in the plurality of subcircuits,
a multiplier circuit coupled to the sense amplifier circuit and the input latch circuit, the multiplier circuit comprising a plurality of multipliers in the plurality of subcircuits, and
an adder circuit coupled to the multiplier circuit.

13. The memory device of claim 12, wherein the circuitry is configured for execution of a computing instruction in one or more memory units of the plurality of memory units, the one or more memory units comprising the memory unit, and wherein the peripheral circuit of the memory unit is configured to perform a computing operation corresponding to the computing instruction, and
wherein the sense amplifier circuit is configured to read weight data from corresponding memory cells in the memory cell array, wherein the input latch circuit is configured to receive input data from the circuitry, wherein the multiplier circuit is configured to multiply the weight data by the input data to obtain a plurality of multiplication results, and wherein the adder circuit configured to add the plurality of multiplication results to obtain a sum corresponding to the computing operation.

14. A memory device, comprising:
a plurality of memory units; and
a circuitry coupled to the plurality of memory units and configured for execution of a computing instruction in one or more memory units of the plurality of memory units, the circuitry comprising a first sense amplifier external to the plurality of memory units,
wherein a memory unit of the plurality of memory units comprises:
a memory cell array comprising memory cells; and
a peripheral circuit comprising a plurality of subcircuits coupled to the memory cell array, each subcircuit of the plurality of subcircuits comprising: one or more second sense amplifiers, one or more latches, and one or more multipliers, and
wherein the circuitry is configured to:
determine whether a subcircuit is defective by determining whether at least one of a second sense amplifier, a latch, or a multiplier in the subcircuit is defective using the first sense amplifier, and
in response to determining that the subcircuit is defective, perform one or more corresponding actions comprising replacing the subcircuit with a redundant subcircuit in the peripheral circuit.

15. The memory device of claim 14, wherein the circuitry is configured to:
remap stored data in corresponding memory cells coupled to the subcircuit to redundant memory cells coupled to a redundant subcircuit, and
remap input data loaded in the one or more latches of the subcircuit to one or more redundant latches of the redundant subcircuit.

16. The memory device of claim 14, wherein the peripheral circuit comprises an adder circuit coupled to the plurality of subcircuits, and
wherein the circuitry is configured to, in response to determining that the subcircuit is defective, clear the one or more latches of the subcircuit with a value of “0”.

17. The memory device of claim 14, wherein the subcircuit further comprises:
one or more first transistors, each of the one or more first transistors being coupled between a second sense amplifier of the one or more second sense amplifiers and a bit line that is coupled to the first sense amplifier,
wherein the second sense amplifier is configured to read data from a memory cell via the bit line and output the data read by the second sense amplifier through the first transistor via the bit line to the first sense amplifier, and
wherein the circuitry is configured to: determine whether the second sense amplifier of the subcircuit is defective based on a result of the first sense amplifier sensing the data read from the memory cell by the second sense amplifier.

18. The memory device of claim 17, wherein the subcircuit further comprises:
one or more second transistors, each of the one or more second transistors being coupled between a corresponding multiplier of the one or more multipliers and a corresponding bit line,
wherein the subcircuit is configured to: turn off a connection between the corresponding multiplier and a corresponding second sense amplifier, and output, by the corresponding multiplier, an output based on input data from a corresponding latch via the corresponding bit line to the first sense amplifier, and
wherein the circuitry is configured to determine whether at least one of the corresponding latch or the corresponding multiplier is defective based on a result of the first sense amplifier sensing the output by the corresponding multiplier.

19. The memory device of claim 18, wherein the subcircuit further comprises: a connection transistor having a first terminal coupled to an output of the corresponding second sense amplifier, a second terminal coupled to a first input of the corresponding multiplier, and a connection gate terminal,
wherein the output of the corresponding sense amplifier is coupled to a first terminal of a corresponding first transistor, and the corresponding bit line is coupled to a second terminal of the corresponding first transistor, and
wherein the second transistor comprises a first terminal coupled to an output of the corresponding multiplier, and a second terminal coupled to the first terminal of the corresponding first transistor.

20. A method, comprising:
determining whether a subcircuit of a peripheral circuit of a memory unit of a memory device is defective by a first sense amplifier sensing an output of the subcircuit, wherein the memory device comprises a plurality of memory units and a circuitry coupled to the plurality of memory units, the first sense amplifier is external to the plurality of memory units, the memory unit comprises a memory cell array and the peripheral circuit having a plurality of subcircuits coupled to the memory cell array, and the subcircuit comprises: one or more second sense amplifiers, one or more latches, and one or more multipliers; and
in response to determining that the subcircuit is defective, performing one or more corresponding actions comprising replacing the subcircuit with a redundant subcircuit in the peripheral circuit.

21. The method of claim 20, wherein performing the one or more corresponding actions comprises one or more of:
marking the subcircuit as a defective subcircuit,
storing a corresponding address for the at least one of the corresponding memory cell or the subcircuit as a failed address in the circuitry,
remapping stored data in corresponding memory cells coupled to the subcircuit to redundant memory cells coupled to the redundant subcircuit in the peripheral circuit,
remapping input data loaded in the one or more latches of the subcircuit to one or more redundant latches of the redundant subcircuit, and
clearing the one or more latches of the subcircuit with a value of “0”.
